(19) United States
(12) Patent Application Publication
(10) Pub. No.: US 2024/0193038 A1
(43) Pub. Date: Jun. 13, 2024

(54) INTELLIGENT CHARACTERISTIC BASED STORAGE DEVICE ALLOCATION IN A STORAGE SYSTEM

(71) Applicant: PURE STORAGE, INC, SANTA CLARA, CA (US)

(72) Inventors: ETHAN MILLER, SANTA CRUZ, CA (US); JOHN COLGROVE, LOS ALTOS, CA (US); ROBERT LEE, PEBBLE BEACH, CA (US)

(21) Appl. No.: 18/582,098

(22) Filed: Feb. 20, 2024

Related U.S. Application Data
(63) Continuation-in-part of application No. 15/994,035, filed on May 31, 2018.
Application No. 15/994,035 is a continuation-in-part of application No. 15/799,907, filed on Oct. 31, 2017, now abandoned.
(63) Continuation-in-part of application No. 18/540,338, filed on Dec. 14, 2023.
Application No. 18/540,338 is a continuation of application No. 17/085,906, filed on Oct. 30, 2020, now Pat. No. 11,886,288.
Application No. 17/085,906 is a continuation of application No. 15/592,069, filed on May 10, 2017, now Pat. No. 10,831,594.
Application No. 15/592,069 is a continuation of application No. 15/292,004, filed on Oct. 12, 2016, now Pat. No. 9,672,905.
(60) Provisional application No. 62/365,852, filed on Jul. 22, 2016.

(51) Int. Cl. G06F 11/10; G06F 3/06; G06F 12/02; G11C 11/56; G11C 16/34

(52) U.S. Cl. CPC G06F 11/1044; G06F 3/0611; G06F 3/0616; G06F 3/0619; G06F 3/065; G06F 3/0659; G06F 3/0679; G06F 3/0688; G06F 12/0246; G11C 11/5628; G11C 16/3495; G06F 2212/7211

(57) ABSTRACT

Corresponding performance characteristics for storage devices are identified. A calculation is performed using the corresponding performance characteristics for the storage devices. A set of storage devices is allocated for storage of shards of a redundant array of independent drives (RAID) stripe based on results of the calculation.

### CROSS REFERENCE TO RELATED APPLICATIONS

This application is a continuation-in-part application for patent entitled to a filing date and claiming the benefit of earlier-filed U.S. patent application Ser. No. 15/994,035, filed May 31, 2018, which is a continuation-in-part application of U.S. patent application Ser. No. 15/799,907, filed Oct. 31, 2017, both of which are hereby incorporated herein by reference in their entirety.

This application is also a continuation-in-part application for patent entitled to a filing date and claiming the benefit of carlier-filed U.S. patent application Ser. No. 18/540,338, filed Dec. 14, 2023, which is a continuation application of U.S. patent application Ser. No. 17/085,906, filed Oct. 30, 2020, issued as U.S. Pat. No. 11,886,288 on Jan. 30, 2024, which is a continuation application of U.S. patent application Ser. No. 15/592,069, filed May 10, 2017, issued as U.S. Pat. No. 10,831,594 on Nov. 10, 2020, which is a continuation application of U.S. patent application Ser. No. 15/292,004, filed Oct. 12, 2016, issued as U.S. Pat. No. 9,672,905 on Jun. 6, 2017, which claims the benefit of carlier-filed U.S. Provisional Patent Application Ser. No. 62/365,852, filed Jul. 22, 2016, all of which are hereby incorporated herein by reference in their entirety.

### BACKGROUND

Various flash memory devices of various flash types (SLC or single level cell, MLC or multilevel cell, QLC or quad level cell, a type of multilevel cell, etc.) from various manufacturers have various requirements or recommendations for data writes for filling in word lines and/or cells, in order to achieve best read reliability. As examples of flash device-based filling needs, some flash memories are specified for multilevel cell operation with the requirement that the bits for each of the lower page, upper page and extra page be filled for each cell. Some flash memories have recommendations of specified sets of partner pages, for filling of word lines. Some flash memories have the recommendation that one specified set of pages does not need to be partnered (i.e., can be written, but without requirement for filling any other pages) and another set of pages does need to be partnered (i.e., can be written, but the other partner pages should be written to complete filling of word line(s)). There are even examples of flash memories that have word lines with one or more SLC bits and one or more MLC bits on the same word line. These requirements or recommendations pose further problems in mixed-device (heterogeneous) implementations of storage memory. Once a data stripe (or series of data stripes) is written, there may be a word line that remains unfilled, in one or more of the flash memory devices. Over time, many such word lines remain unfilled, reducing read reliability. Also, various flash memories have various failure mechanisms, such as stuck word lines that affect multiple pages. Therefore, there is a need in the art for a solution which solves the problems described above.

### SUMMARY

In some embodiments, a geometry-aware method of writing parity, performed by a storage system is provided. The method includes writing data, using error correction coding, to a RAID stripe comprising a plurality of allocation units of storage memory of the storage system, and writing one or more parity pages comprising parity data for a block having a portion of the data of the RAID stripe in one of the plurality of allocation units of the RAID stripe to a targeted differing word line of the block or a differing block, the parity data for the block distinct from the error correction coding of the RAID stripe.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

The present disclosure is illustrated by way of example, and not by way of limitation, and can be more fully understood with reference to the following detailed description when considered in connection with the figures as described below.

FIG. 1A illustrates a first example system for data storage in accordance with some implementations.

FIG. 1B illustrates a second example system for data storage in accordance with some implementations.

FIG. 1C illustrates a third example system for data storage in accordance with some implementations.

FIG. 1D illustrates a fourth example system for data storage in accordance with some implementations.

FIG. 2A is a perspective view of a storage cluster with multiple storage nodes and internal storage coupled to each storage node to provide network attached storage, in accordance with some embodiments.

FIG. 2B is a block diagram showing an interconnect switch coupling multiple storage nodes in accordance with some embodiments.

FIG. 2C is a multiple level block diagram, showing contents of a storage node and contents of one of the non-volatile solid state storage units in accordance with some embodiments.

FIG. 2D shows a storage server environment, which uses embodiments of the storage nodes and storage units of FIGS. 1-3 in accordance with some embodiments.

FIG. 2E is a blade hardware block diagram, showing a control plane, compute and storage planes, and authorities interacting with underlying physical resources, in accordance with some embodiments.

FIG. 2F depicts elasticity software layers in blades of a storage cluster, in accordance with some embodiments.

FIG. 2G depicts authorities and storage resources in blades of a storage cluster, in accordance with some embodiments.

FIG. 3A sets forth a diagram of a storage system that is coupled for data communications with a cloud services provider in accordance with some embodiments of the present disclosure.

FIG. 3B sets forth a diagram of a storage system in accordance with some embodiments of the present disclosure.

FIG. 4 depicts an example of NAND flash memory structure, showing word lines, bit lines and cells in accordance with some embodiments.

FIG. 5 depicts writing to flash memory in a geometry-aware, two-dimensional parity process to meet flash device-based filling needs in accordance with some embodiments.

FIG. 6 sets forth an embodiment of a storage system with a word lines or cells filling level tracker that employs direct-mapped writes to flash memory and the geometry-aware, two-dimensional parity process of FIG. 5 in accordance with some embodiments.

FIG. 7 is a flow diagram of a method of geometry-aware parity writing, which can be performed by storage systems described herein, and further storage systems in accordance with some embodiments.

FIG. 8 is an illustration showing an exemplary computing device which may implement the embodiments described herein.

FIG. 9 depicts a storage system with RAID stripes in storage memory, showing error correction code (ECC) data and parity data for the error correction code data in accordance with some embodiments.

FIG. 10 depicts an embodiment of a storage system with a memory geometry aware analysis module in cooperation with authorities, writing error correction code data and parity data in accordance with some embodiments.

FIG. 11 illustrates allocation units of storage memory in RAID stripes in accordance with some embodiments.

FIG. 12 depicts heterogeneous block sizes, allocation unit sizes and block membership in allocation units in embodiments of storage memory in accordance with some embodiments.

FIG. 13 illustrates locations of parity data for the error correction code data, as arranged by the storage systems depicted in FIGS. 9 and 10 in accordance with some embodiments.

FIG. 14 depicts error correction code data and parity data written along various word lines in storage memory in accordance with some embodiments.

FIG. 15 depicts error correction code data and parity data written to different types of solid-state storage memory in accordance with some embodiments.

FIG. 16 depicts the hierarchy of logical unit numbers (LUNs), blocks and pages in embodiments of solid-state storage memory in accordance with some embodiments.

FIG. 17 is a flow diagram of a geometry-aware method of writing parity in a storage system in accordance with some embodiments.

FIG. 18 is an illustration of an example of a storage system controller of a storage system performing a calculation using performance characteristics of a storage device, in accordance with embodiments of the disclosure.

FIG. 19 is an illustration of an example of a storage system controller allocating storage devices of a storage system for storing data based on results of a calculation, in accordance with embodiments of the disclosure.

FIG. 20 is an example method to allocate storage devices based on performance characteristics, in accordance with embodiments of the disclosure.

### DETAILED DESCRIPTION

Various embodiments of storage systems, and configurable, geometry-aware, two-dimensional parity processes are described herein. For a data stripe, data bits and parity bits are determined by a storage system according to error correction code, as a first step in the geometry-aware, two-dimensional parity process. For the second step, the storage system tracks occupancy or filling of word lines and/or multilevel cells in flash memory devices. Data bits (or pages of data bits, i.e., parity pages) are written according to an addressing scheme and address translation, but the parity bits (or parity pages) are specifically targeted for filling unfilled word lines and/or unfilled multilevel cells, based on the tracking of the occupancy or filling of word lines and/or multilevel cells. Thus, the geometry-aware, two-dimensional parity process involves “horizontal” writing of parity, as parity of data stripes, and “vertical” writing of parity, as specific placement of parity bits or parity pages according to the needs of filling word lines and/or filling multilevel flash cells, in flash memory devices.

The specific placement of parity bits or pages of parity bits, i.e., parity pages, is configurable, direct mapped from the host (e.g., a storage unit or storage controller), and supports multiple NAND flash memory devices concurrently in a storage memory. It is not necessarily the case that all parity bits or parity pages are placed to fill word lines or multilevel cells. Some parity bits or parity pages could be placed according to the addressing scheme and address translation by which data bits or pages of data bits are placed (i.e., independently of word line or cell filling), and others could be placed to fill word lines or multilevel cells on an as-needed basis (for the word lines and cells) or as available (for parity bits or parity pages).

In another embodiment, a geometry-aware parity process writes parity data to selected physical locations in solid-state storage memory so as to improve survivability of the parity data in the face of failure mechanisms of solid-state storage memory. In various embodiments, error correction code data of RAID stripes has distinct parity data which is written to different word lines, blocks, types of single or multilevel cell solid-state storage memory, or logical unit numbers than the error correction code data, so that one will more likely survive if the other is subjected to a failure of part of physical memory. A storage system that is aware of the geometry of the solid-state memory and the failure mechanisms can select target regions to write the parity data to increase the chances that the error correction code data and parity data for that error correction code data are not both subject to the same failure, thereby improving reliability of the system.

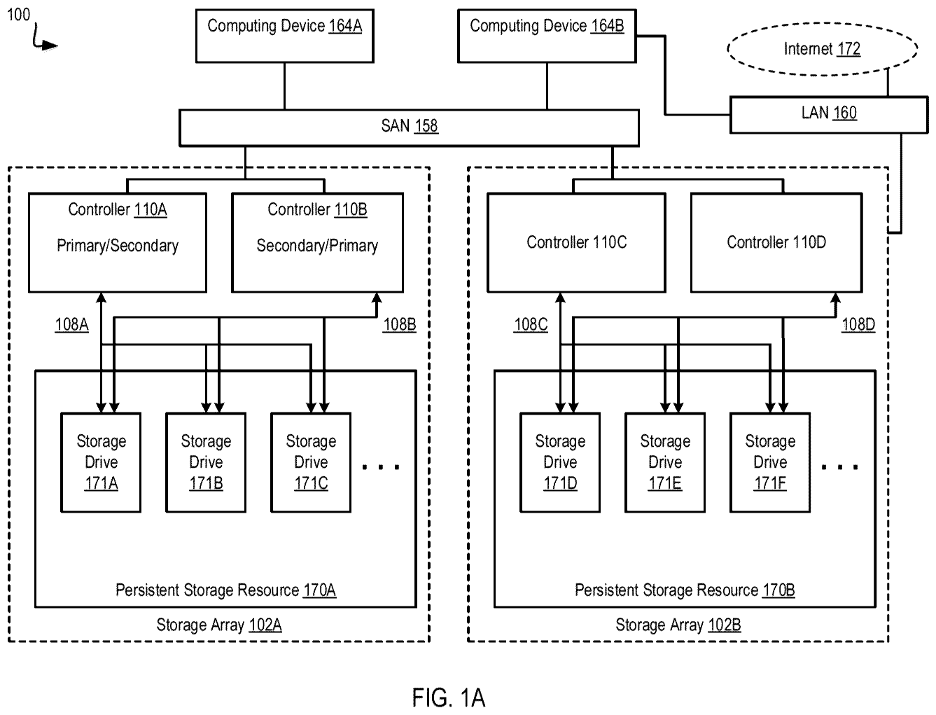

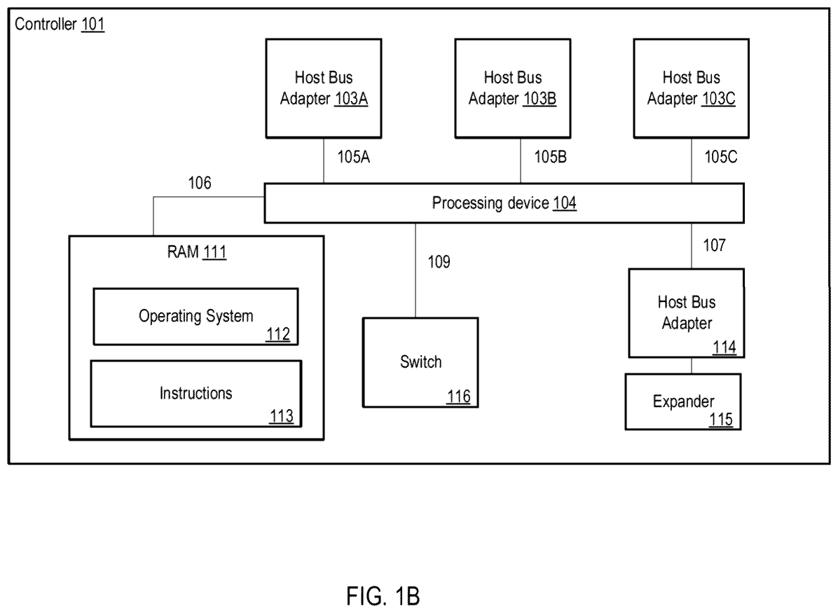

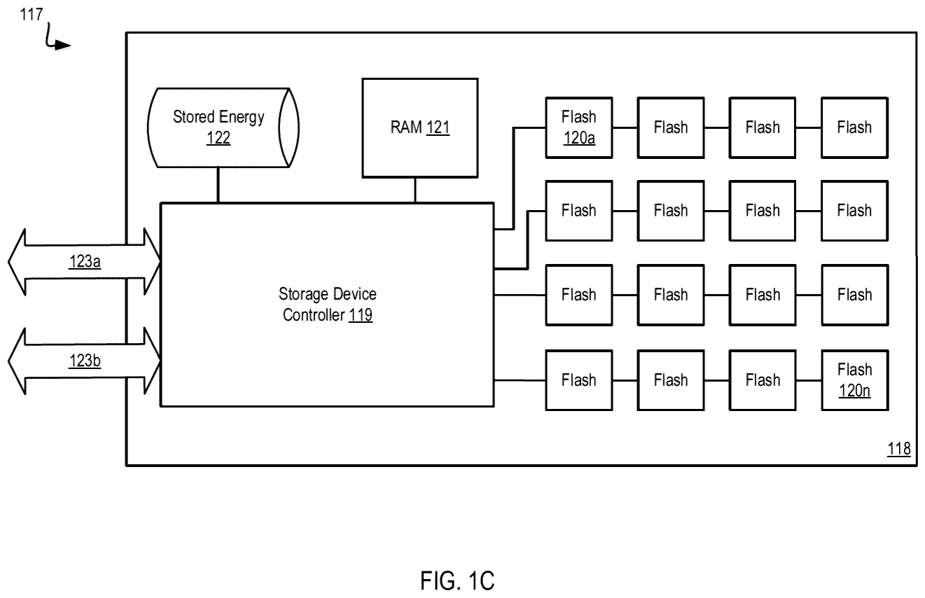

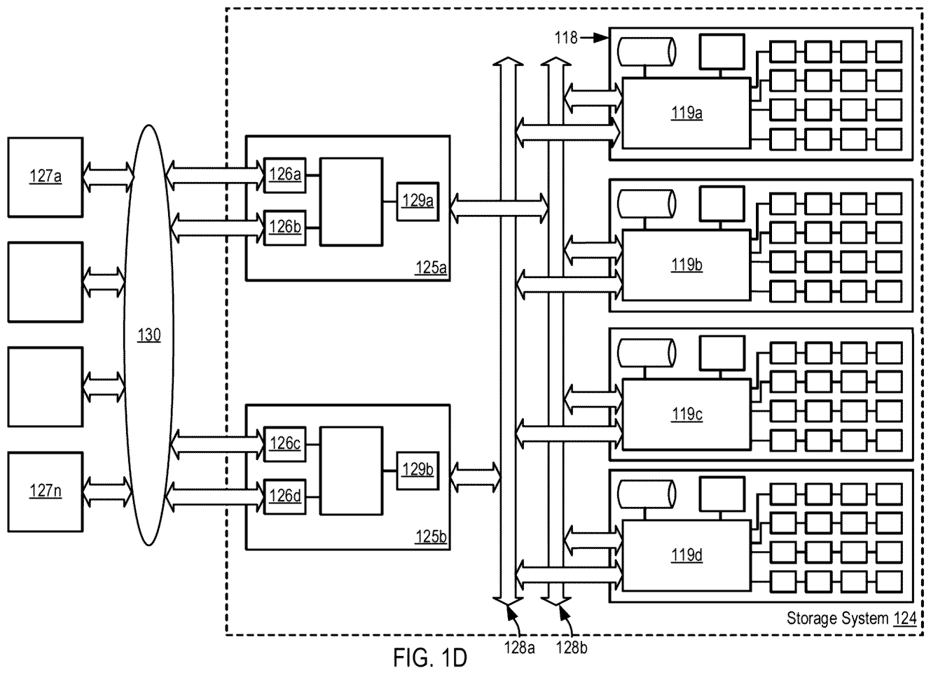

FIG. 1A illustrates an example system for data storage, in accordance with some implementations. System 100 (also referred to as “storage system” herein) includes numerous elements for purposes of illustration rather than limitation. It may be noted that system 100 may include the same, more, or fewer elements configured in the same or different manner in other implementations.

System 100 includes a number of computing devices 164. Computing devices (also referred to as “client devices” herein) may be for example, a server in a data center, a workstation, a personal computer, a notebook, or the like. Computing devices 164 are coupled for data communications to one or more storage arrays 102 through a storage area network (SAN) 158 or a local area network (LAN) 160.

The SAN 158 may be implemented with a variety of data communications fabrics, devices, and protocols. For example, the fabrics for SAN 158 may include Fibre Channel, Ethernet, Infiniband, Serial Attached Small Computer System Interface (SAS), or the like. Data communications protocols for use with SAN 158 may include Advanced Technology Attachment (ATA), Fibre Channel Protocol, Small Computer System Interface (SCSI), Internet Small Computer System Interface (iSCSI), HyperSCSI, Non-Volatile Memory Express (NVMe) over Fabrics, or the like. It may be noted that SAN 158 is provided for illustration, rather than limitation. Other data communication couplings may be implemented between computing devices 164 and storage arrays 102.

The LAN 160 may also be implemented with a variety of fabrics, devices, and protocols. For example, the fabrics for LAN 160 may include Ethernet (802.3), wireless (802.11), or the like. Data communication protocols for use in LAN 160 may include Transmission Control Protocol (TCP), User Datagram Protocol (UDP), Internet Protocol (IP), HyperText Transfer Protocol (HTTP), Wireless Access Protocol (WAP), Handheld Device Transport Protocol (HDTP), Session Initiation Protocol (SIP), Real Time Protocol (RTP), or the like.

Storage arrays 102 may provide persistent data storage for the computing devices 164. Storage array 102A may be contained in a chassis (not shown), and storage array 102B may be contained in another chassis (not shown), in implementations. Storage array 102A and 102B may include one or more storage array controllers 110 (also referred to as “controller” herein). A storage array controller 110 may be embodied as a module of automated computing machinery comprising computer hardware, computer software, or a combination of computer hardware and software. In some implementations, the storage array controllers 110 may be configured to carry out various storage tasks. Storage tasks may include writing data received from the computing devices 164 to storage array 102, erasing data from storage array 102, retrieving data from storage array 102 and providing data to computing devices 164, monitoring and reporting of disk utilization and performance, performing redundancy operations, such as Redundant Array of Independent Drives (RAID) or RAID-like data redundancy operations, compressing data, encrypting data, and so forth.

Storage array controller 110 may be implemented in a variety of ways, including as a Field Programmable Gate Array (FPGA), a Programmable Logic Chip (PLC), an Application Specific Integrated Circuit (ASIC), System-on-Chip (SOC), or any computing device that includes discrete components such as a processing device, central processing unit, computer memory, or various adapters. Storage array controller 110 may include, for example, a data communications adapter configured to support communications via the SAN 158 or LAN 160. In some implementations, storage array controller 110 may be independently coupled to the LAN 160. In implementations, storage array controller 110 may include an I/O controller or the like that couples the storage array controller 110 for data communications, through a midplane (not shown), to a persistent storage resource 170 (also referred to as a “storage resource” herein). The persistent storage resource 170 main include any number of storage drives 171 (also referred to as “storage devices” herein) and any number of non-volatile Random Access Memory (NVRAM) devices (not shown).

In some implementations, the NVRAM devices of a persistent storage resource 170 may be configured to receive, from the storage array controller 110, data to be stored in the storage drives 171. In some examples, the data may originate from computing devices 164. In some examples, writing data to the NVRAM device may be carried out more quickly than directly writing data to the storage drive 171. In implementations, the storage array controller 110 may be configured to utilize the NVRAM devices as a quickly accessible buffer for data destined to be written to the storage drives 171. Latency for write requests using NVRAM devices as a buffer may be improved relative to a system in which a storage array controller 110 writes data directly to the storage drives 171. In some implementations, the NVRAM devices may be implemented with computer memory in the form of high bandwidth, low latency RAM. The NVRAM device is referred to as “non-volatile” because the NVRAM device may receive or include a unique power source that maintains the state of the RAM after main power loss to the NVRAM device. Such a power source may be a battery, one or more capacitors, or the like. In response to a power loss, the NVRAM device may be configured to write the contents of the RAM to a persistent storage, such as the storage drives 171.

In implementations, storage drive 171 may refer to any device configured to record data persistently, where “persistently” or “persistent” refers as to a device's ability to maintain recorded data after loss of power. In some implementations, storage drive 171 may correspond to non-disk storage media. For example, the storage drive 171 may be one or more solid-state drives (SSDs), flash memory based storage, any type of solid-state non-volatile memory, or any other type of non-mechanical storage device. In other implementations, storage drive 171 may include mechanical or spinning hard disk, such as hard-disk drives (HDD).

In some implementations, the storage array controllers 110 may be configured for offloading device management responsibilities from storage drive 171 in storage array 102. For example, storage array controllers 110 may manage control information that may describe the state of one or more memory blocks in the storage drives 171. The control information may indicate, for example, that a particular memory block has failed and should no longer be written to, that a particular memory block contains boot code for a storage array controller 110, the number of program-erase (P/E) cycles that have been performed on a particular memory block, the age of data stored in a particular memory block, the type of data that is stored in a particular memory block, and so forth. In some implementations, the control information may be stored with an associated memory block as metadata. In other implementations, the control information for the storage drives 171 may be stored in one or more particular memory blocks of the storage drives 171 that are selected by the storage array controller 110. The selected memory blocks may be tagged with an identifier indicating that the selected memory block contains control information. The identifier may be utilized by the storage array controllers 110 in conjunction with storage drives 171 to quickly identify the memory blocks that contain control information. For example, the storage controllers 110 may issue a command to locate memory blocks that contain control information. It may be noted that control information may be so large that parts of the control information may be stored in multiple locations, that the control information may be stored in multiple locations for purposes of redundancy, for example, or that the control information may otherwise be distributed across multiple memory blocks in the storage drive 171.

In implementations, storage array controllers 110 may offload device management responsibilities from storage drives 171 of storage array 102 by retrieving, from the storage drives 171, control information describing the state of one or more memory blocks in the storage drives 171. Retrieving the control information from the storage drives 171 may be carried out, for example, by the storage array controller 110 querying the storage drives 171 for the location of control information for a particular storage drive 171. The storage drives 171 may be configured to execute instructions that enable the storage drive 171 to identify the location of the control information. The instructions may be executed by a controller (not shown) associated with or otherwise located on the storage drive 171 and may cause the storage drive 171 to scan a portion of each memory block to identify the memory blocks that store control information for the storage drives 171. The storage drives 171 may respond by sending a response message to the storage array controller 110 that includes the location of control information for the storage drive 171. Responsive to receiving the response message, storage array controllers 110 may issue a request to read data stored at the address associated with the location of control information for the storage drives 171.

In other implementations, the storage array controllers 110 may further offload device management responsibilities from storage drives 171 by performing, in response to receiving the control information, a storage drive management operation. A storage drive management operation may include, for example, an operation that is typically performed by the storage drive 171 (e.g., the controller (not shown) associated with a particular storage drive 171). A storage drive management operation may include, for example, ensuring that data is not written to failed memory blocks within the storage drive 171, ensuring that data is written to memory blocks within the storage drive 171 in such a way that adequate wear leveling is achieved, and so forth.

In implementations, storage array 102 may implement two or more storage array controllers 110. For example, storage array 102A may include storage array controllers 110A and storage array controllers 110B. At a given instance, a single storage array controller 110 (e.g., storage array controller 110A) of a storage system 100 may be designated with primary status (also referred to as “primary controller” herein), and other storage array controllers 110 (e.g., storage array controller 110A) may be designated with secondary status (also referred to as “secondary controller” herein). The primary controller may have particular rights, such as permission to alter data in persistent storage resource 170 (e.g., writing data to persistent storage resource 170). At least some of the rights of the primary controller may supersede the rights of the secondary controller. For instance, the secondary controller may not have permission to alter data in persistent storage resource 170 when the primary controller has the right. The status of storage array controllers 110 may change. For example, storage array controller 110A may be designated with secondary status, and storage array controller 110B may be designated with primary status.

In some implementations, a primary controller, such as storage array controller 110A, may serve as the primary controller for one or more storage arrays 102, and a second controller, such as storage array controller 110B, may serve as the secondary controller for the one or more storage arrays 102. For example, storage array controller 110A may be the primary controller for storage array 102A and storage array 102B, and storage array controller 110B may be the secondary controller for storage array 102A and 102B. In some implementations, storage array controllers 110C and 110D (also referred to as “storage processing modules”) may neither have primary or secondary status. Storage array controllers 110C and 110D, implemented as storage processing modules, may act as a communication interface between the primary and secondary controllers (e.g., storage array controllers 110A and 110B, respectively) and storage array 102B. For example, storage array controller 110A of storage array 102A may send a write request, via SAN 158, to storage array 102B. The write request may be received by both storage array controllers 110C and 110D of storage array 102B. Storage array controllers 110C and 110D facilitate the communication, e.g., send the write request to the appropriate storage drive 171. It may be noted that in some implementations storage processing modules may be used to increase the number of storage drives controlled by the primary and secondary controllers.

In implementations, storage array controllers 110 are communicatively coupled, via a midplane (not shown), to one or more storage drives 171 and to one or more NVRAM devices (not shown) that are included as part of a storage array 102. The storage array controllers 110 may be coupled to the midplane via one or more data communication links and the midplane may be coupled to the storage drives 171 and the NVRAM devices via one or more data communications links. The data communications links described herein are collectively illustrated by data communications links 108 and may include a Peripheral Component Interconnect Express (PCIe) bus, for example.

FIG. 1B illustrates an example system for data storage, in accordance with some implementations. Storage array controller 101 illustrated in FIG. 1B may similar to the storage array controllers 110 described with respect to FIG. 1A. In one example, storage array controller 101 may be similar to storage array controller 110A or storage array controller 110B. Storage array controller 101 includes numerous elements for purposes of illustration rather than limitation. It may be noted that storage array controller 101 may include the same, more, or fewer elements configured in the same or different manner in other implementations. It may be noted that elements of FIG. 1A may be included below to help illustrate features of storage array controller 101.

Storage array controller 101 may include one or more processing devices 104 and random access memory (RAM) 111. Processing device 104 (or controller 101) represents one or more general-purpose processing devices such as a microprocessor, central processing unit, or the like. More particularly, the processing device 104 (or controller 101) may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 104 (or controller 101) may also be one or more special-purpose processing devices such as an application specific integrated circuit (ASIC), a field programmable gate array (FPGA), a digital signal processor (DSP), network processor, or the like.

The processing device 104 may be connected to the RAM 111 via a data communications link 106, which may be embodied as a high speed memory bus such as a Double-Data Rate 4 (DDR4) bus. Stored in RAM 111 is an operating system 112. In some implementations, instructions 113 are stored in RAM 111. Instructions 113 may include computer program instructions for performing operations in a direct-mapped flash storage system. In one embodiment, a direct-mapped flash storage system is one that addresses data blocks within flash drives directly and without an address translation performed by the storage controllers of the flash drives.

In implementations, storage array controller 101 includes one or more host bus adapters 103 that are coupled to the processing device 104 via a data communications link 105. In implementations, host bus adapters 103 may be computer hardware that connects a host system (e.g., the storage array controller) to other network and storage arrays. In some examples, host bus adapters 103 may be a Fibre Channel adapter that enables the storage array controller 101 to connect to a SAN, an Ethernet adapter that enables the storage array controller 101 to connect to a LAN, or the like. Host bus adapters 103 may be coupled to the processing device 104 via a data communications link 105 such as, for example, a PCIe bus.

In implementations, storage array controller 101 may include a host bus adapter 114 that is coupled to an expander 115. The expander 115 may be used to attach a host system to a larger number of storage drives. The expander 115 may, for example, be a SAS expander utilized to enable the host bus adapter 114 to attach to storage drives in an implementation where the host bus adapter 114 is embodied as a SAS controller.

In implementations, storage array controller 101 may include a switch 116 coupled to the processing device 104 via a data communications link 109. The switch 116 may be a computer hardware device that can create multiple endpoints out of a single endpoint, thereby enabling multiple devices to share a single endpoint. The switch 116 may, for example, be a PCIe switch that is coupled to a PCIe bus (e.g., data communications link 109) and presents multiple PCIe connection points to the midplane.

In implementations, storage array controller 101 includes a data communications link 107 for coupling the storage array controller 101 to other storage array controllers. In some examples, data communications link 107 may be a QuickPath Interconnect (QPI) interconnect.

A traditional storage system that uses traditional flash drives may implement a process across the flash drives that are part of the traditional storage system. For example, a higher level process of the storage system may initiate and control a process across the flash drives. However, a flash drive of the traditional storage system may include its own storage controller that also performs the process. Thus, for the traditional storage system, a higher level process (e.g., initiated by the storage system) and a lower level process (e.g., initiated by a storage controller of the storage system) may both be performed.

To resolve various deficiencies of a traditional storage system, operations may be performed by higher level processes and not by the lower level processes. For example, the flash storage system may include flash drives that do not include storage controllers that provide the process. Thus, the operating system of the flash storage system itself may initiate and control the process. This may be accomplished by a direct-mapped flash storage system that addresses data blocks within the flash drives directly and without an address translation performed by the storage controllers of the flash drives.

The operating system of the flash storage system may identify and maintain a list of allocation units across multiple flash drives of the flash storage system. The allocation units may be entire erase blocks or multiple erase blocks. The operating system may maintain a map or address range that directly maps addresses to erase blocks of the flash drives of the flash storage system.

Direct mapping to the erase blocks of the flash drives may be used to rewrite data and erase data. For example, the operations may be performed on one or more allocation units that include a first data and a second data where the first data is to be retained and the second data is no longer being used by the flash storage system. The operating system may initiate the process to write the first data to new locations within other allocation units and erasing the second data and marking the allocation units as being available for use for subsequent data. Thus, the process may only be performed by the higher level operating system of the flash storage system without an additional lower level process being performed by controllers of the flash drives.

Advantages of the process being performed only by the operating system of the flash storage system include increased reliability of the flash drives of the flash storage system as unnecessary or redundant write operations are not being performed during the process. One possible point of novelty here is the concept of initiating and controlling the process at the operating system of the flash storage system. In addition, the process can be controlled by the operating system across multiple flash drives. This is contrast to the process being performed by a storage controller of a flash drive.

A storage system can consist of two storage array controllers that share a set of drives for failover purposes, or it could consist of a single storage array controller that provides a storage service that utilizes multiple drives, or it could consist of a distributed network of storage array controllers each with some number of drives or some amount of Flash storage where the storage array controllers in the network collaborate to provide a complete storage service and collaborate on various aspects of a storage service including storage allocation and garbage collection.

FIG. 1C illustrates a third example system 117 for data storage in accordance with some implementations. System 117 (also referred to as “storage system” herein) includes numerous elements for purposes of illustration rather than limitation. It may be noted that system 117 may include the same, more, or fewer elements configured in the same or different manner in other implementations.

In one embodiment, system 117 includes a dual Peripheral Component Interconnect (PCI) flash storage device 118 with separately addressable fast write storage. System 117 may include a storage controller 119. In one embodiment, storage controller 119 may be a CPU, ASIC, FPGA, or any other circuitry that may implement control structures necessary according to the present disclosure. In one embodiment, system 117 includes flash memory devices (e.g., including flash memory devices 120a-n), operatively coupled to various channels of the storage device controller 119. Flash memory devices 120a-n, may be presented to the controller 119 as an addressable collection of Flash pages, erase blocks, and/or control elements sufficient to allow the storage device controller 119 to program and retrieve various aspects of the Flash. In one embodiment, storage device controller 119 may perform operations on flash memory devices 120A-N including storing and retrieving data content of pages, arranging and erasing any blocks, tracking statistics related to the use and reuse of Flash memory pages, erase blocks, and cells, tracking and predicting error codes and faults within the Flash memory, controlling voltage levels associated with programming and retrieving contents of Flash cells, etc.

In one embodiment, system 117 may include random access memory (RAM) 121 to store separately addressable fast-write data. In one embodiment, RAM 121 may be one or more separate discrete devices. In another embodiment, RAM 121 may be integrated into storage device controller 119 or multiple storage device controllers. The RAM 121 may be utilized for other purposes as well, such as temporary program memory for a processing device (E.g., a central processing unit (CPU)) in the storage device controller 119.

In one embodiment, system 117 may include a stored energy device 122, such as a rechargeable battery or a capacitor. Stored energy device 122 may store energy sufficient to power the storage device controller 119, some amount of the RAM (e.g., RAM 121), and some amount of Flash memory (e.g., Flash memory 120a-120n) for sufficient time to write the contents of RAM to Flash memory. In one embodiment, storage device controller 119 may write the contents of RAM to Flash Memory if the storage device controller detects loss of external power.

In one embodiment, system 117 includes two data communications links 123a, 123b. In one embodiment, data communications links 123a, 123b may be PCI interfaces. In another embodiment, data communications links 123a, 123b may be based on other communications standards (e.g., HyperTransport, InfiBand, etc.). Data communications links 123a, 123b may be based on non-volatile memory express (NVMe) or NCMe over fabrics (NVMf) specifications that allow external connection to the storage device controller 119 from other components in the storage system 117. It should be noted that data communications links may be interchangeably referred to herein as PCI buses for convenience.

System 117 may also include an external power source (not shown), which may be provided over one or both data communications links 123a, 123b, or which may be provided separately. An alternative embodiment includes a separate Flash memory (not shown) dedicated for use in storing the content of RAM 121. The storage device controller 119 may present a logical device over a PCI bus which may include an addressable fast-write logical device, or a distinct part of the logical address space of the storage device 118, which may be presented as PCI memory or as persistent storage. In one embodiment, operations to store into the device are directed into the RAM 121. On power failure, the storage device controller 119 may write stored content associated with the addressable fast-write logical storage to Flash memory (e.g., Flash memory 120a-n) for long-term persistent storage.

In one embodiment, the logical device may include some presentation of some or all of the content of the Flash memory devices 120a-n, where that presentation allows a storage system including a storage device 118 (e.g., storage system 117) to directly address Flash memory pages and directly reprogram erase blocks from storage system components that are external to the storage device through the PCI bus. The presentation may also allow one or more of the external components to control and retrieve other aspects of the Flash memory including some or all of: tracking statistics related to use and reuse of Flash memory pages, erase blocks, and cells across all the Flash memory devices; tracking and predicting error codes and faults within and across the Flash memory devices; controlling voltage levels associated with programming and retrieving contents of Flash cells; etc.

In one embodiment, the stored energy device 122 may be sufficient to ensure completion of in-progress operations to the Flash memory devices 107a-120n stored energy device 122 may power storage device controller 119 and associated Flash memory devices (e.g., 120a-n) for those operations, as well as for the storing of fast-write RAM to Flash memory. Stored energy device 122 may be used to store accumulated statistics and other parameters kept and tracked by the Flash memory devices 120a-n and/or the storage device controller 119. Separate capacitors or stored energy devices (such as smaller capacitors near or embedded within the Flash memory devices themselves) may be used for some or all of the operations described herein.

Various schemes may be used to track and optimize the life span of the stored energy component, such as adjusting voltage levels over time, partially discharging the storage energy device 122 to measure corresponding discharge characteristics, etc. If the available energy decreases over time, the effective available capacity of the addressable fast-write storage may be decreased to ensure that it can be written safely based on the currently available stored energy.

FIG. 1D illustrates a third example system 124 for data storage in accordance with some implementations. In one embodiment, system 124 includes storage controllers 125a, 125b. In one embodiment, storage controllers 125a, 125b are operatively coupled to Dual PCI storage devices 119a, 119b and 119c, 119d, respectively. Storage controllers 125a, 125b may be operatively coupled (e.g., via a storage network 130) to some number of host computers 127a-n.

In one embodiment, two storage controllers (e.g., 125a and 125b) provide storage services, such as a small computer system interface (SCSI) block storage array, a file server, an object server, a database or data analytics service, etc. The storage controllers 125a, 125b may provide services through some number of network interfaces (e.g., 126a-d) to host computers 127a-n outside of the storage system 124. Storage controllers 125a, 125b may provide integrated services or an application entirely within the storage system 124, forming a converged storage and compute system. The storage controllers 125a, 125b may utilize the fast write memory within or across storage devices 119a-d to journal in progress operations to ensure the operations are not lost on a power failure, storage controller removal, storage controller or storage system shutdown, or some fault of one or more software or hardware components within the storage system 124.

In one embodiment, controllers 125a, 125b operate as PCI masters to one or the other PCI buses 128a, 128b. In another embodiment, 128a and 128b may be based on other communications standards (e.g., HyperTransport, InfiBand, etc.). Other storage system embodiments may operate storage controllers 125a, 125b as multi-masters for both PCI buses 128a, 128b. Alternately, a PCI/NVMe/NVMf switching infrastructure or fabric may connect multiple storage controllers. Some storage system embodiments may allow storage devices to communicate with each other directly rather than communicating only with storage controllers. In one embodiment, a storage device controller 119a may be operable under direction from a storage controller 125a to synthesize and transfer data to be stored into Flash memory devices from data that has been stored in RAM (e.g., RAM 121 of FIG. 1C). For example, a recalculated version of RAM content may be transferred after a storage controller has determined that an operation has fully committed across the storage system, or when fast-write memory on the device has reached a certain used capacity, or after a certain amount of time, to ensure improve safety of the data or to release addressable fast-write capacity for reuse. This mechanism may be used, for example, to avoid a second transfer over a bus (e.g., 128a, 128b) from the storage controllers 125a, 125b. In one embodiment, a recalculation may include compressing data, attaching indexing or other metadata, combining multiple data segments together, performing erasure code calculations, etc.

In one embodiment, under direction from a storage controller 125a, 125b, a storage device controller 119a, 119b may be operable to calculate and transfer data to other storage devices from data stored in RAM (e.g., RAM 121 of FIG. 1C) without involvement of the storage controllers 125a, 125b. This operation may be used to mirror data stored in one controller 125a to another controller 125b, or it could be used to offload compression, data aggregation, and/or erasure coding calculations and transfers to storage devices to reduce load on storage controllers or the storage controller interface 129a, 129b to the PCI bus 128a, 128b.

A storage device controller 119 may include mechanisms for implementing high availability primitives for use by other parts of a storage system external to the Dual PCI storage device 118. For example, reservation or exclusion primitives may be provided so that, in a storage system with two storage controllers providing a highly available storage service, one storage controller may prevent the other storage controller from accessing or continuing to access the storage device. This could be used, for example, in cases where one controller detects that the other controller is not functioning properly or where the interconnect between the two storage controllers may itself not be functioning properly.

In one embodiment, a storage system for use with Dual PCI direct mapped storage devices with separately addressable fast write storage includes systems that manage erase blocks or groups of erase blocks as allocation units for storing data on behalf of the storage service, or for storing metadata (e.g., indexes, logs, etc.) associated with the storage service, or for proper management of the storage system itself. Flash pages, which may be a few kilobytes in size, may be written as data arrives or as the storage system is to persist data for long intervals of time (e.g., above a defined threshold of time). To commit data more quickly, or to reduce the number of writes to the Flash memory devices, the storage controllers may first write data into the separately addressable fast write storage on one or more storage devices.

In one embodiment, the storage controllers 125a, 125b may initiate the use of erase blocks within and across storage devices (e.g., 118) in accordance with an age and expected remaining lifespan of the storage devices, or based on other statistics. The storage controllers 125a, 125b may initiate garbage collection and data migration between storage devices in accordance with pages that are no longer needed as well as to manage Flash page and erase block lifespans and to manage overall system performance.

In one embodiment, the storage system 124 may utilize mirroring and/or erasure coding schemes as part of storing data into addressable fast write storage and/or as part of writing data into allocation units associated with erase blocks. Erasure codes may be used across storage devices, as well as within erase blocks or allocation units, or within and across Flash memory devices on a single storage device, to provide redundancy against single or multiple storage device failures or to protect against internal corruptions of Flash memory pages resulting from Flash memory operations or from degradation of Flash memory cells. Mirroring and erasure coding at various levels may be used to recover from multiple types of failures that occur separately or in combination.

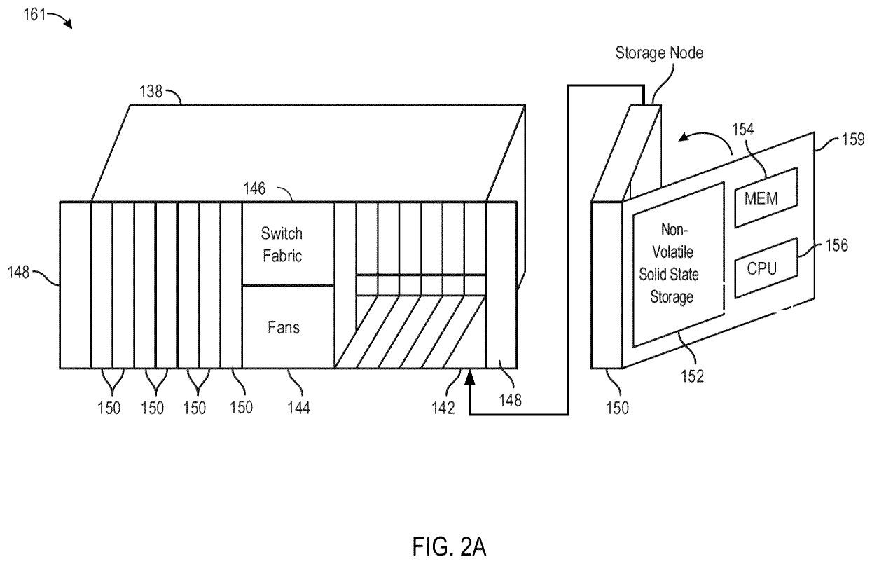

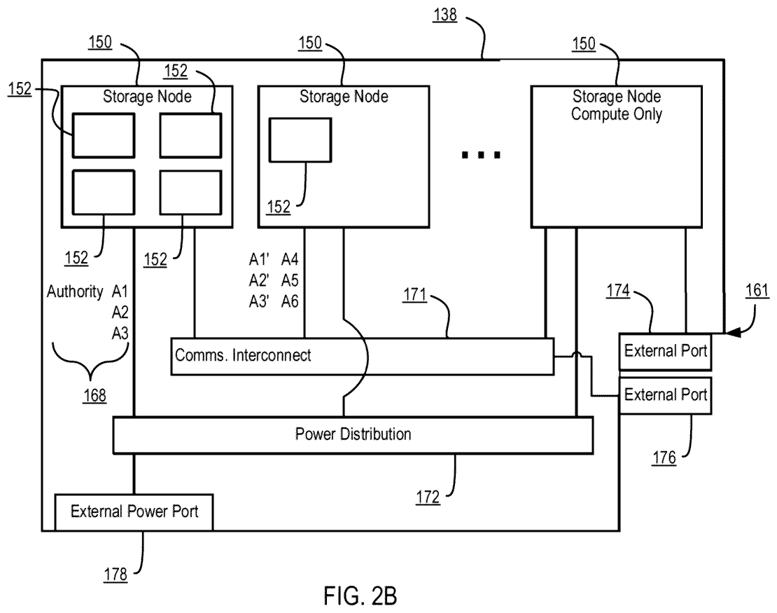

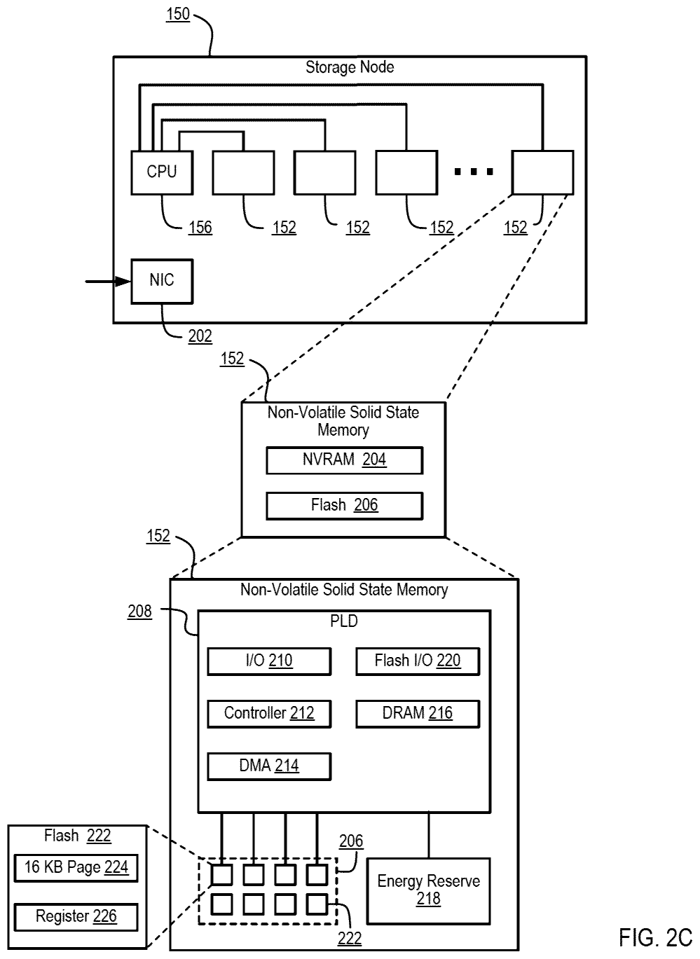

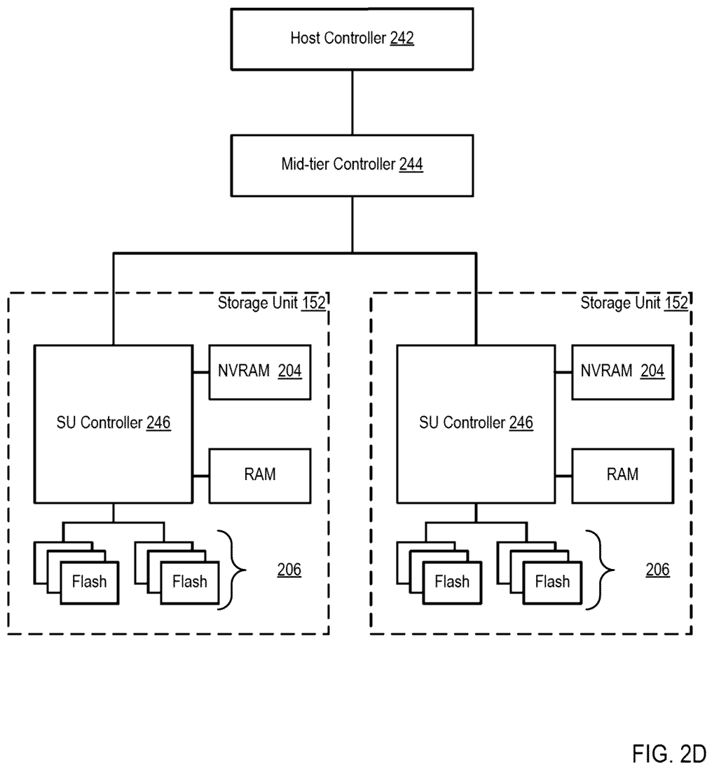

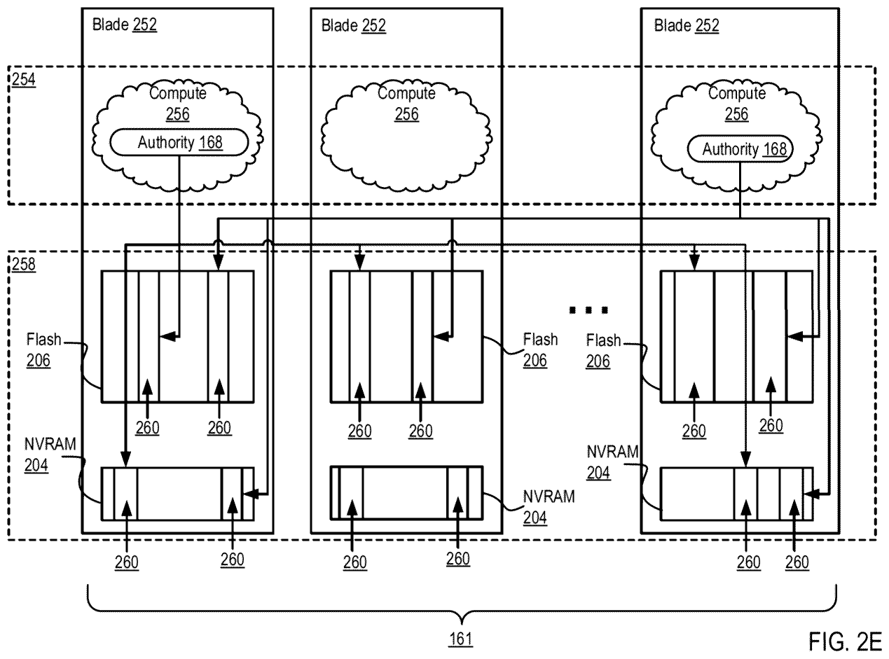

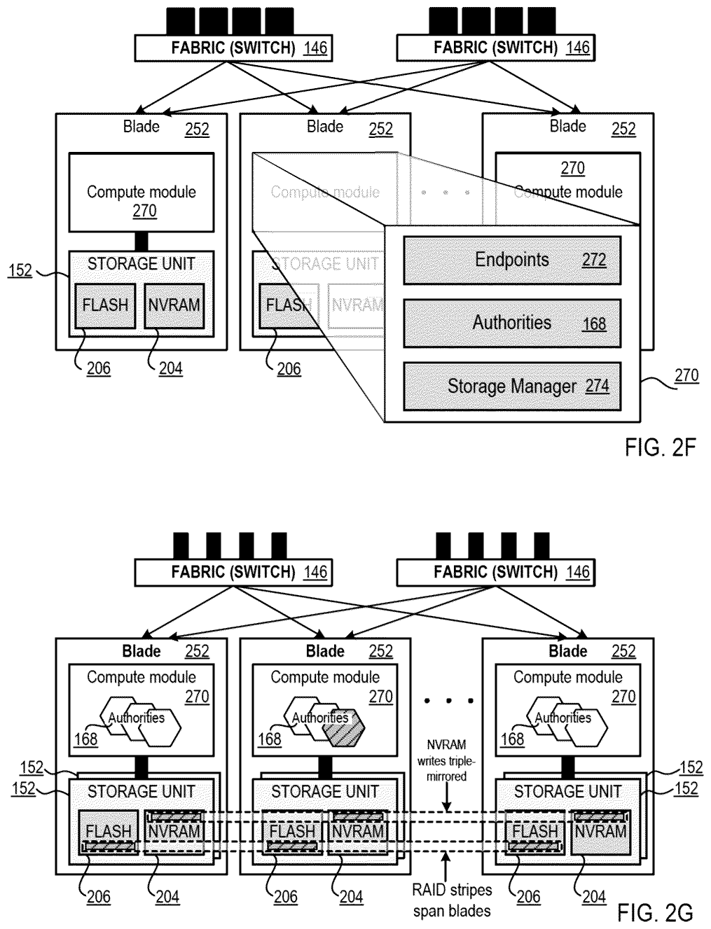

The embodiments depicted with reference to FIGS. 2A-G illustrate a storage cluster that stores user data, such as user data originating from one or more user or client systems or other sources external to the storage cluster. The storage cluster distributes user data across storage nodes housed within a chassis, or across multiple chassis, using erasure coding and redundant copies of metadata. Erasure coding refers to a method of data protection or reconstruction in which data is stored across a set of different locations, such as disks, storage nodes or geographic locations. Flash memory is one type of solid-state memory that may be integrated with the embodiments, although the embodiments may be extended to other types of solid-state memory or other storage medium, including non-solid state memory. Control of storage locations and workloads are distributed across the storage locations in a clustered peer-to-peer system. Tasks such as mediating communications between the various storage nodes, detecting when a storage node has become unavailable, and balancing I/Os (inputs and outputs) across the various storage nodes, are all handled on a distributed basis. Data is laid out or distributed across multiple storage nodes in data fragments or stripes that support data recovery in some embodiments. Ownership of data can be reassigned within a cluster, independent of input and output patterns. This architecture described in more detail below allows a storage node in the cluster to fail, with the system remaining operational, since the data can be reconstructed from other storage nodes and thus remain available for input and output operations. In various embodiments, a storage node may be referred to as a cluster node, a blade, or a server.

The storage cluster may be contained within a chassis, i.e., an enclosure housing one or more storage nodes. A mechanism to provide power to each storage node, such as a power distribution bus, and a communication mechanism, such as a communication bus that enables communication between the storage nodes are included within the chassis. The storage cluster can run as an independent system in one location according to some embodiments. In one embodiment, a chassis contains at least two instances of both the power distribution and the communication bus which may be enabled or disabled independently. The internal communication bus may be an Ethernet bus, however, other technologies such as Peripheral Component Interconnect (PCI) Express, InfiniBand, and others, are equally suitable. The chassis provides a port for an external communication bus for enabling communication between multiple chassis, directly or through a switch, and with client systems. The external communication may use a technology such as Ethernet, InfiniBand, Fibre Channel, etc. In some embodiments, the external communication bus uses different communication bus technologies for inter-chassis and client communication. If a switch is deployed within or between chassis, the switch may act as a translation between multiple protocols or technologies. When multiple chassis are connected to define a storage cluster, the storage cluster may be accessed by a client using either proprietary interfaces or standard interfaces such as network file system (NFS), common internet file system (CIFS), small computer system interface (SCSI) or hypertext transfer protocol (HTTP). Translation from the client protocol may occur at the switch, chassis external communication bus or within each storage node. In some embodiments, multiple chassis may be coupled or connected to each other through an aggregator switch. A portion and/or all of the coupled or connected chassis may be designated as a storage cluster. As discussed above, each chassis can have multiple blades, each blade has a MAC (media access control) address, but the storage cluster is presented to an external network as having a single cluster IP (Internet Protocol) address and a single MAC address in some embodiments.

Each storage node may be one or more storage servers and each storage server is connected to one or more non-volatile solid state memory units, which may be referred to as storage units or storage devices. One embodiment includes a single storage server in each storage node and between one to eight non-volatile solid state memory units, however this one example is not meant to be limiting. The storage server may include a processor, dynamic random access memory (DRAM) and interfaces for the internal communication bus and power distribution for each of the power buses. Inside the storage node, the interfaces and storage unit share a communication bus, e.g., PCI Express, in some embodiments. The non-volatile solid state memory units may directly access the internal communication bus interface through a storage node communication bus, or request the storage node to access the bus interface. The non-volatile solid state memory unit contains an embedded central processing unit (CPU), solid state storage controller, and a quantity of solid state mass storage, e.g., between 2-32 terabytes (TB) in some embodiments. An embedded volatile storage medium, such as DRAM, and an energy reserve apparatus are included in the non-volatile solid state memory unit. In some embodiments, the energy reserve apparatus is a capacitor, super-capacitor, or battery that enables transferring a subset of DRAM contents to a stable storage medium in the case of power loss. In some embodiments, the non-volatile solid state memory unit is constructed with a storage class memory, such as phase change or magnetoresistive random access memory (MRAM) that substitutes for DRAM and enables a reduced power hold-up apparatus.

One of many features of the storage nodes and non-volatile solid state storage is the ability to proactively rebuild data in a storage cluster. The storage nodes and non-volatile solid state storage can determine when a storage node or non-volatile solid state storage in the storage cluster is unreachable, independent of whether there is an attempt to read data involving that storage node or non-volatile solid state storage. The storage nodes and non-volatile solid state storage then cooperate to recover and rebuild the data in at least partially new locations. This constitutes a proactive rebuild, in that the system rebuilds data without waiting until the data is needed for a read access initiated from a client system employing the storage cluster. These and further details of the storage memory and operation thereof are discussed below.

FIG. 2A is a perspective view of a storage cluster 161, with multiple storage nodes 150 and internal solid-state memory coupled to each storage node to provide network attached storage or storage area network, in accordance with some embodiments. A network attached storage, storage area network, or a storage cluster, or other storage memory, could include one or more storage clusters 161, each having one or more storage nodes 150, in a flexible and reconfigurable arrangement of both the physical components and the amount of storage memory provided thereby. The storage cluster 161 is designed to fit in a rack, and one or more racks can be set up and populated as desired for the storage memory. The storage cluster 161 has a chassis 138 having multiple slots 142. It should be appreciated that chassis 138 may be referred to as a housing, enclosure, or rack unit. In one embodiment, the chassis 138 has fourteen slots 142, although other numbers of slots are readily devised. For example, some embodiments have four slots, eight slots, sixteen slots, thirty-two slots, or other suitable number of slots. Each slot 142 can accommodate one storage node 150 in some embodiments. Chassis 138 includes flaps 148 that can be utilized to mount the chassis 138 on a rack. Fans 144 provide air circulation for cooling of the storage nodes 150 and components thereof, although other cooling components could be used, or an embodiment could be devised without cooling components. A switch fabric 146 couples storage nodes 150 within chassis 138 together and to a network for communication to the memory. In an embodiment depicted in FIG. 1, the slots 142 to the left of the switch fabric 146 and fans 144 are shown occupied by storage nodes 150, while the slots 142 to the right of the switch fabric 146 and fans 144 are empty and available for insertion of storage node 150 for illustrative purposes. This configuration is one example, and one or more storage nodes 150 could occupy the slots 142 in various further arrangements. The storage node arrangements need not be sequential or adjacent in some embodiments. Storage nodes 150 are hot pluggable, meaning that a storage node 150 can be inserted into a slot 142 in the chassis 138, or removed from a slot 142, without stopping or powering down the system. Upon insertion or removal of storage node 150 from slot 142, the system automatically reconfigures in order to recognize and adapt to the change. Reconfiguration, in some embodiments, includes restoring redundancy and/or rebalancing data or load.

Each storage node 150 can have multiple components. In the embodiment shown here, the storage node 150 includes a printed circuit board 159 populated by a CPU 156, i.e., processor, a memory 154 coupled to the CPU 156, and a non-volatile solid state storage 152 coupled to the CPU 156, although other mountings and/or components could be used in further embodiments. The memory 154 has instructions which are executed by the CPU 156 and/or data operated on by the CPU 156. As further explained below, the non-volatile solid state storage 152 includes flash or, in further embodiments, other types of solid-state memory.

Referring to FIG. 2A, storage cluster 161 is scalable, meaning that storage capacity with non-uniform storage sizes is readily added, as described above. One or more storage nodes 150 can be plugged into or removed from each chassis and the storage cluster self-configures in some embodiments. Plug-in storage nodes 150, whether installed in a chassis as delivered or later added, can have different sizes. For example, in one embodiment a storage node 150 can have any multiple of 4 TB, e.g., 8 TB, 12 TB, 16 TB, 32 TB, etc. In further embodiments, a storage node 150 could have any multiple of other storage amounts or capacities. Storage capacity of each storage node 150 is broadcast, and influences decisions of how to stripe the data. For maximum storage efficiency, an embodiment can self-configure as wide as possible in the stripe, subject to a predetermined requirement of continued operation with loss of up to one, or up to two, non-volatile solid state storage units 152 or storage nodes 150 within the chassis.

FIG. 2B is a block diagram showing a communications interconnect 171 and power distribution bus 172 coupling multiple storage nodes 150. Referring back to FIG. 2A, the communications interconnect 171 can be included in or implemented with the switch fabric 146 in some embodiments. Where multiple storage clusters 161 occupy a rack, the communications interconnect 171 can be included in or implemented with a top of rack switch, in some embodiments. As illustrated in FIG. 2B, storage cluster 161 is enclosed within a single chassis 138. External port 176 is coupled to storage nodes 150 through communications interconnect 171, while external port 174 is coupled directly to a storage node. External power port 178 is coupled to power distribution bus 172. Storage nodes 150 may include varying amounts and differing capacities of non-volatile solid state storage 152 as described with reference to FIG. 2A. In addition, one or more storage nodes 150 may be a compute only storage node as illustrated in FIG. 2B. Authorities 168 are implemented on the non-volatile solid state storages 152, for example as lists or other data structures stored in memory. In some embodiments the authorities are stored within the non-volatile solid state storage 152 and supported by software executing on a controller or other processor of the non-volatile solid state storage 152. In a further embodiment, authorities 168 are implemented on the storage nodes 150, for example as lists or other data structures stored in the memory 154 and supported by software executing on the CPU 156 of the storage node 150. Authorities 168 control how and where data is stored in the non-volatile solid state storages 152 in some embodiments. This control assists in determining which type of erasure coding scheme is applied to the data, and which storage nodes 150 have which portions of the data. Each authority 168 may be assigned to a non-volatile solid state storage 152. Each authority may control a range of inode numbers, segment numbers, or other data identifiers which are assigned to data by a file system, by the storage nodes 150, or by the non-volatile solid state storage 152, in various embodiments.

Every piece of data, and every piece of metadata, has redundancy in the system in some embodiments. In addition, every piece of data and every piece of metadata has an owner, which may be referred to as an authority. If that authority is unreachable, for example through failure of a storage node, there is a plan of succession for how to find that data or that metadata. In various embodiments, there are redundant copies of authorities 168. Authorities 168 have a relationship to storage nodes 150 and non-volatile solid state storage 152 in some embodiments. Each authority 168, covering a range of data segment numbers or other identifiers of the data, may be assigned to a specific non-volatile solid state storage 152. In some embodiments the authorities 168 for all of such ranges are distributed over the non-volatile solid state storages 152 of a storage cluster. Each storage node 150 has a network port that provides access to the non-volatile solid state storage(s) 152 of that storage node 150. Data can be stored in a segment, which is associated with a segment number and that segment number is an indirection for a configuration of a RAID (redundant array of independent disks) stripe in some embodiments. The assignment and use of the authorities 168 thus establishes an indirection to data. Indirection may be referred to as the ability to reference data indirectly, in this case via an authority 168, in accordance with some embodiments. A segment identifies a set of non-volatile solid state storage 152 and a local identifier into the set of non-volatile solid state storage 152 that may contain data. In some embodiments, the local identifier is an offset into the device and may be reused sequentially by multiple segments. In other embodiments the local identifier is unique for a specific segment and never reused. The offsets in the non-volatile solid state storage 152 are applied to locating data for writing to or reading from the non-volatile solid state storage 152 (in the form of a RAID stripe). Data is striped across multiple units of non-volatile solid state storage 152, which may include or be different from the non-volatile solid state storage 152 having the authority 168 for a particular data segment.

If there is a change in where a particular segment of data is located, e.g., during a data move or a data reconstruction, the authority 168 for that data segment should be consulted, at that non-volatile solid state storage 152 or storage node 150 having that authority 168. In order to locate a particular piece of data, embodiments calculate a hash value for a data segment or apply an inode number or a data segment number. The output of this operation points to a non-volatile solid state storage 152 having the authority 168 for that particular piece of data. In some embodiments there are two stages to this operation. The first stage maps an entity identifier (ID), e.g., a segment number, inode number, or directory number to an authority identifier. This mapping may include a calculation such as a hash or a bit mask. The second stage is mapping the authority identifier to a particular non-volatile solid state storage 152, which may be done through an explicit mapping. The operation is repeatable, so that when the calculation is performed, the result of the calculation repeatably and reliably points to a particular non-volatile solid state storage 152 having that authority 168. The operation may include the set of reachable storage nodes as input. If the set of reachable non-volatile solid state storage units changes the optimal set changes. In some embodiments, the persisted value is the current assignment (which is always true) and the calculated value is the target assignment the cluster will attempt to reconfigure towards. This calculation may be used to determine the optimal non-volatile solid state storage 152 for an authority in the presence of a set of non-volatile solid state storage 152 that are reachable and constitute the same cluster. The calculation also determines an ordered set of peer non-volatile solid state storage 152 that will also record the authority to non-volatile solid state storage mapping so that the authority may be determined even if the assigned non-volatile solid state storage is unreachable. A duplicate or substitute authority 168 may be consulted if a specific authority 168 is unavailable in some embodiments.

With reference to FIGS. 2A and 2B, two of the many tasks of the CPU 156 on a storage node 150 are to break up write data, and reassemble read data. When the system has determined that data is to be written, the authority 168 for that data is located as above. When the segment ID for data is already determined the request to write is forwarded to the non-volatile solid state storage 152 currently determined to be the host of the authority 168 determined from the segment. The host CPU 156 of the storage node 150, on which the non-volatile solid state storage 152 and corresponding authority 168 reside, then breaks up or shards the data and transmits the data out to various non-volatile solid state storage 152. The transmitted data is written as a data stripe in accordance with an erasure coding scheme. In some embodiments, data is requested to be pulled, and in other embodiments, data is pushed. In reverse, when data is read, the authority 168 for the segment ID containing the data is located as described above. The host CPU 156 of the storage node 150 on which the non-volatile solid state storage 152 and corresponding authority 168 reside requests the data from the non-volatile solid state storage and corresponding storage nodes pointed to by the authority. In some embodiments the data is read from flash storage as a data stripe. The host CPU 156 of storage node 150 then reassembles the read data, correcting any errors (if present) according to the appropriate erasure coding scheme, and forwards the reassembled data to the network. In further embodiments, some or all of these tasks can be handled in the non-volatile solid state storage 152. In some embodiments, the segment host requests the data be sent to storage node 150 by requesting pages from storage and then sending the data to the storage node making the original request.

In some systems, for example in UNIX-style file systems, data is handled with an index node or inode, which specifies a data structure that represents an object in a file system. The object could be a file or a directory, for example. Metadata may accompany the object, as attributes such as permission data and a creation timestamp, among other attributes. A segment number could be assigned to all or a portion of such an object in a file system. In other systems, data segments are handled with a segment number assigned elsewhere. For purposes of discussion, the unit of distribution is an entity, and an entity can be a file, a directory or a segment. That is, entities are units of data or metadata stored by a storage system. Entities are grouped into sets called authorities. Each authority has an authority owner, which is a storage node that has the exclusive right to update the entities in the authority. In other words, a storage node contains the authority, and that the authority, in turn, contains entities.

A segment is a logical container of data in accordance with some embodiments. A segment is an address space between medium address space and physical flash locations, i.e., the data segment number, are in this address space. Segments may also contain meta-data, which enable data redundancy to be restored (rewritten to different flash locations or devices) without the involvement of higher level software. In one embodiment, an internal format of a segment contains client data and medium mappings to determine the position of that data. Each data segment is protected, e.g., from memory and other failures, by breaking the segment into a number of data and parity shards, where applicable. The data and parity shards are distributed, i.e., striped, across non-volatile solid state storage 152 coupled to the host CPUs 156 (See FIGS. 2E and 2G) in accordance with an erasure coding scheme. Usage of the term segments refers to the container and its place in the address space of segments in some embodiments. Usage of the term stripe refers to the same set of shards as a segment and includes how the shards are distributed along with redundancy or parity information in accordance with some embodiments.

A series of address-space transformations takes place across an entire storage system. At the top are the directory entries (file names) which link to an inode. Inodes point into medium address space, where data is logically stored. Medium addresses may be mapped through a series of indirect mediums to spread the load of large files, or implement data services like deduplication or snapshots. Segment addresses are then translated into physical flash locations. Physical flash locations have an address range bounded by the amount of flash in the system in accordance with some embodiments. Medium addresses and segment addresses are logical containers, and in some embodiments use a 128 bit or larger identifier so as to be practically infinite, with a likelihood of reuse calculated as longer than the expected life of the system. Addresses from logical containers are allocated in a hierarchical fashion in some embodiments. Initially, each non-volatile solid state storage unit 152 may be assigned a range of address space. Within this assigned range, the non-volatile solid state storage 152 is able to allocate addresses without synchronization with other non-volatile solid state storage 152.

Data and metadata is stored by a set of underlying storage layouts that are optimized for varying workload patterns and storage devices. These layouts incorporate multiple redundancy schemes, compression formats and index algorithms. Some of these layouts store information about authorities and authority masters, while others store file metadata and file data. The redundancy schemes include error correction codes that tolerate corrupted bits within a single storage device (such as a NAND flash chip), erasure codes that tolerate the failure of multiple storage nodes, and replication schemes that tolerate data center or regional failures. In some embodiments, low density parity check (LDPC) code is used within a single storage unit. Reed-Solomon encoding is used within a storage cluster, and mirroring is used within a storage grid in some embodiments. Metadata may be stored using an ordered log structured index (such as a Log Structured Merge Tree), and large data may not be stored in a log structured layout.

In order to maintain consistency across multiple copies of an entity, the storage nodes agree implicitly on two things through calculations: (1) the authority that contains the entity, and (2) the storage node that contains the authority. The assignment of entities to authorities can be done by pseudo randomly assigning entities to authorities, by splitting entities into ranges based upon an externally produced key, or by placing a single entity into each authority. Examples of pseudorandom schemes are linear hashing and the Replication Under Scalable Hashing (RUSH) family of hashes, including Controlled Replication Under Scalable Hashing (CRUSH). In some embodiments, pseudo-random assignment is utilized only for assigning authorities to nodes because the set of nodes can change. The set of authorities cannot change so any subjective function may be applied in these embodiments. Some placement schemes automatically place authorities on storage nodes, while other placement schemes rely on an explicit mapping of authorities to storage nodes. In some embodiments, a pseudorandom scheme is utilized to map from each authority to a set of candidate authority owners. A pseudorandom data distribution function related to CRUSH may assign authorities to storage nodes and create a list of where the authorities are assigned. Each storage node has a copy of the pseudorandom data distribution function, and can arrive at the same calculation for distributing, and later finding or locating an authority. Each of the pseudorandom schemes requires the reachable set of storage nodes as input in some embodiments in order to conclude the same target nodes. Once an entity has been placed in an authority, the entity may be stored on physical devices so that no expected failure will lead to unexpected data loss. In some embodiments, rebalancing algorithms attempt to store the copies of all entities within an authority in the same layout and on the same set of machines.

Examples of expected failures include device failures, stolen machines, datacenter fires, and regional disasters, such as nuclear or geological events. Different failures lead to different levels of acceptable data loss. In some embodiments, a stolen storage node impacts neither the security nor the reliability of the system, while depending on system configuration, a regional event could lead to no loss of data, a few seconds or minutes of lost updates, or even complete data loss.

In the embodiments, the placement of data for storage redundancy is independent of the placement of authorities for data consistency. In some embodiments, storage nodes that contain authorities do not contain any persistent storage. Instead, the storage nodes are connected to non-volatile solid state storage units that do not contain authorities. The communications interconnect between storage nodes and non-volatile solid state storage units consists of multiple communication technologies and has non-uniform performance and fault tolerance characteristics. In some embodiments, as mentioned above, non-volatile solid state storage units are connected to storage nodes via PCI express, storage nodes are connected together within a single chassis using Ethernet backplane, and chassis are connected together to form a storage cluster. Storage clusters are connected to clients using Ethernet or fiber channel in some embodiments. If multiple storage clusters are configured into a storage grid, the multiple storage clusters are connected using the Internet or other long-distance networking links, such as a “metro scale” link or private link that does not traverse the internet.

Authority owners have the exclusive right to modify entities, to migrate entities from one non-volatile solid state storage unit to another non-volatile solid state storage unit, and to add and remove copies of entities. This allows for maintaining the redundancy of the underlying data. When an authority owner fails, is going to be decommissioned, or is overloaded, the authority is transferred to a new storage node. Transient failures make it non-trivial to ensure that all non-faulty machines agree upon the new authority location. The ambiguity that arises due to transient failures can be achieved automatically by a consensus protocol such as Paxos, hot-warm failover schemes, via manual intervention by a remote system administrator, or by a local hardware administrator (such as by physically removing the failed machine from the cluster, or pressing a button on the failed machine). In some embodiments, a consensus protocol is used, and failover is automatic. If too many failures or replication events occur in too short a time period, the system goes into a self-preservation mode and halts replication and data movement activities until an administrator intervenes in accordance with some embodiments.

As authorities are transferred between storage nodes and authority owners update entities in their authorities, the system transfers messages between the storage nodes and non-volatile solid state storage units. With regard to persistent messages, messages that have different purposes are of different types. Depending on the type of the message, the system maintains different ordering and durability guarantees. As the persistent messages are being processed, the messages are temporarily stored in multiple durable and non-durable storage hardware technologies. In some embodiments, messages are stored in RAM, NVRAM and on NAND flash devices, and a variety of protocols are used in order to make efficient use of each storage medium. Latency-sensitive client requests may be persisted in replicated NVRAM, and then later NAND, while background rebalancing operations are persisted directly to NAND.

Persistent messages are persistently stored prior to being transmitted. This allows the system to continue to serve client requests despite failures and component replacement. Although many hardware components contain unique identifiers that are visible to system administrators, manufacturer, hardware supply chain and ongoing monitoring quality control infrastructure, applications running on top of the infrastructure address virtualize addresses. These virtualized addresses do not change over the lifetime of the storage system, regardless of component failures and replacements. This allows each component of the storage system to be replaced over time without reconfiguration or disruptions of client request processing, i.e., the system supports non-disruptive upgrades.

In some embodiments, the virtualized addresses are stored with sufficient redundancy. A continuous monitoring system correlates hardware and software status and the hardware identifiers. This allows detection and prediction of failures due to faulty components and manufacturing details. The monitoring system also enables the proactive transfer of authorities and entities away from impacted devices before failure occurs by removing the component from the critical path in some embodiments.

FIG. 2C is a multiple level block diagram, showing contents of a storage node 150 and contents of a non-volatile solid state storage 152 of the storage node 150. Data is communicated to and from the storage node 150 by a network interface controller (NIC) 202 in some embodiments. Each storage node 150 has a CPU 156, and one or more non-volatile solid state storage 152, as discussed above. Moving down one level in FIG. 2C, each non-volatile solid state storage 152 has a relatively fast non-volatile solid state memory, such as nonvolatile random access memory (NVRAM) 204, and flash memory 206. In some embodiments, NVRAM 204 may be a component that does not require program/erase cycles (DRAM, MRAM, PCM), and can be a memory that can support being written vastly more often than the memory is read from. Moving down another level in FIG. 2C, the NVRAM 204 is implemented in one embodiment as high speed volatile memory, such as dynamic random access memory (DRAM) 216, backed up by energy reserve 218. Energy reserve 218 provides sufficient electrical power to keep the DRAM 216 powered long enough for contents to be transferred to the flash memory 206 in the event of power failure. In some embodiments, energy reserve 218 is a capacitor, super-capacitor, battery, or other device, that supplies a suitable supply of energy sufficient to enable the transfer of the contents of DRAM 216 to a stable storage medium in the case of power loss. The flash memory 206 is implemented as multiple flash dies 222, which may be referred to as packages of flash dies 222 or an array of flash dies 222. It should be appreciated that the flash dies 222 could be packaged in any number of ways, with a single die per package, multiple dies per package (i.e. multichip packages), in hybrid packages, as bare dies on a printed circuit board or other substrate, as encapsulated dies, etc. In the embodiment shown, the non-volatile solid state storage 152 has a controller 212 or other processor, and an input output (I/O) port 210 coupled to the controller 212. I/O port 210 is coupled to the CPU 156 and/or the network interface controller 202 of the flash storage node 150. Flash input output (I/O) port 220 is coupled to the flash dies 222, and a direct memory access unit (DMA) 214 is coupled to the controller 212, the DRAM 216 and the flash dies 222. In the embodiment shown, the I/O port 210, controller 212, DMA unit 214 and flash I/O port 220 are implemented on a programmable logic device (PLD) 208, e.g., a field programmable gate array (FPGA). In this embodiment, each flash die 222 has pages, organized as sixteen kB (kilobyte) pages 224, and a register 226 through which data can be written to or read from the flash die 222. In further embodiments, other types of solid-state memory are used in place of, or in addition to flash memory illustrated within flash die 222.

Storage clusters 161, in various embodiments as disclosed herein, can be contrasted with storage arrays in general. The storage nodes 150 are part of a collection that creates the storage cluster 161. Each storage node 150 owns a slice of data and computing required to provide the data. Multiple storage nodes 150 cooperate to store and retrieve the data. Storage memory or storage devices, as used in storage arrays in general, are less involved with processing and manipulating the data. Storage memory or storage devices in a storage array receive commands to read, write, or erase data. The storage memory or storage devices in a storage array are not aware of a larger system in which they are embedded, or what the data means. Storage memory or storage devices in storage arrays can include various types of storage memory, such as RAM, solid state drives, hard disk drives, etc. The storage units 152 described herein have multiple interfaces active simultaneously and serving multiple purposes. In some embodiments, some of the functionality of a storage node 150 is shifted into a storage unit 152, transforming the storage unit 152 into a combination of storage unit 152 and storage node 150. Placing computing (relative to storage data) into the storage unit 152 places this computing closer to the data itself. The various system embodiments have a hierarchy of storage node layers with different capabilities. By contrast, in a storage array, a controller owns and knows everything about all of the data that the controller manages in a shelf or storage devices. In a storage cluster 161, as described herein, multiple controllers in multiple storage units 152 and/or storage nodes 150 cooperate in various ways (e.g., for erasure coding, data sharding, metadata communication and redundancy, storage capacity expansion or contraction, data recovery, and so on).

FIG. 2D shows a storage server environment, which uses embodiments of the storage nodes 150 and storage units 152 of FIGS. 2A-C. In this version, each storage unit 152 has a processor such as controller 212 (see FIG. 2C), an FPGA (field programmable gate array), flash memory 206, and NVRAM 204 (which is super-capacitor backed DRAM 216, see FIGS. 2B and 2C) on a PCIe (peripheral component interconnect express) board in a chassis 138 (see FIG. 2A). The storage unit 152 may be implemented as a single board containing storage, and may be the largest tolerable failure domain inside the chassis. In some embodiments, up to two storage units 152 may fail and the device will continue with no data loss.

The physical storage is divided into named regions based on application usage in some embodiments. The NVRAM 204 is a contiguous block of reserved memory in the storage unit 152 DRAM 216, and is backed by NAND flash. NVRAM 204 is logically divided into multiple memory regions written for two as spool (e.g., spool_region). Space within the NVRAM 204 spools is managed by each authority 168 independently. Each device provides an amount of storage space to each authority 168. That authority 168 further manages lifetimes and allocations within that space. Examples of a spool include distributed transactions or notions. When the primary power to a storage unit 152 fails, onboard super-capacitors provide a short duration of power hold up. During this holdup interval, the contents of the NVRAM 204 are flushed to flash memory 206. On the next power-on, the contents of the NVRAM 204 are recovered from the flash memory 206.

As for the storage unit controller, the responsibility of the logical “controller” is distributed across each of the blades containing authorities 168. This distribution of logical control is shown in FIG. 2D as a host controller 242, mid-tier controller 244 and storage unit controller(s) 246. Management of the control plane and the storage plane are treated independently, although parts may be physically co-located on the same blade. Each authority 168 effectively serves as an independent controller. Each authority 168 provides its own data and metadata structures, its own background workers, and maintains its own lifecycle.

FIG. 2E is a blade 252 hardware block diagram, showing a control plane 254, compute and storage planes 256, 258, and authorities 168 interacting with underlying physical resources, using embodiments of the storage nodes 150 and storage units 152 of FIGS. 2A-C in the storage server environment of FIG. 2D. The control plane 254 is partitioned into a number of authorities 168 which can use the compute resources in the compute plane 256 to run on any of the blades 252. The storage plane 258 is partitioned into a set of devices, each of which provides access to flash 206 and NVRAM 204 resources.

In the compute and storage planes 256, 258 of FIG. 2E, the authorities 168 interact with the underlying physical resources (i.e., devices). From the point of view of an authority 168, its resources are striped over all of the physical devices. From the point of view of a device, it provides resources to all authorities 168, irrespective of where the authorities happen to run. Each authority 168 has allocated or has been allocated one or more partitions 260 of storage memory in the storage units 152, e.g. partitions 260 in flash memory 206 and NVRAM 204. Each authority 168 uses those allocated partitions 260 that belong to it, for writing or reading user data. Authorities can be associated with differing amounts of physical storage of the system. For example, one authority 168 could have a larger number of partitions 260 or larger sized partitions 260 in one or more storage units 152 than one or more other authorities 168.

FIG. 2F depicts elasticity software layers in blades 252 of a storage cluster 161, in accordance with some embodiments. In the elasticity structure, elasticity software is symmetric, i.e., each blade's compute module 270 runs the three identical layers of processes depicted in FIG. 2F. Storage managers 274 execute read and write requests from other blades 252 for data and metadata stored in local storage unit 152 NVRAM 204 and flash 206. Authorities 168 fulfill client requests by issuing the necessary reads and writes to the blades 252 on whose storage units 152 the corresponding data or metadata resides. Endpoints 272 parse client connection requests received from switch fabric 146 supervisory software, relay the client connection requests to the authorities 168 responsible for fulfillment, and relay the authorities' 168 responses to clients. The symmetric three-layer structure enables the storage system's high degree of concurrency. Elasticity scales out efficiently and reliably in these embodiments. In addition, elasticity implements a unique scale-out technique that balances work evenly across all resources regardless of client access pattern, and maximizes concurrency by eliminating much of the need for inter-blade coordination that typically occurs with conventional distributed locking.

Still referring to FIG. 2F, authorities 168 running in the compute modules 270 of a blade 252 perform the internal operations required to fulfill client requests. One feature of elasticity is that authorities 168 are stateless, i.e., they cache active data and metadata in their own blades' 168 DRAMs for fast access, but the authorities store every update in their NVRAM 204 partitions on three separate blades 252 until the update has been written to flash 206. All the storage system writes to NVRAM 204 are in triplicate to partitions on three separate blades 252 in some embodiments. With triple-mirrored NVRAM 204 and persistent storage protected by parity and Reed-Solomon RAID checksums, the storage system can survive concurrent failure of two blades 252 with no loss of data, metadata, or access to either.

Because authorities 168 are stateless, they can migrate between blades 252. Each authority 168 has a unique identifier. NVRAM 204 and flash 206 partitions are associated with authorities' 168 identifiers, not with the blades 252 on which they are running in some. Thus, when an authority 168 migrates, the authority 168 continues to manage the same storage partitions from its new location. When a new blade 252 is installed in an embodiment of the storage cluster 161, the system automatically rebalances load by:
Partitioning the new blade's 252 storage for use by the system's authorities 168,
Migrating selected authorities 168 to the new blade 252,
Starting endpoints 272 on the new blade 252 and including them in the switch fabric's 146 client connection distribution algorithm.

From their new locations, migrated authorities 168 persist the contents of their NVRAM 204 partitions on flash 206, process read and write requests from other authorities 168, and fulfill the client requests that endpoints 272 direct to them. Similarly, if a blade 252 fails or is removed, the system redistributes its authorities 168 among the system's remaining blades 252. The redistributed authorities 168 continue to perform their original functions from their new locations.

FIG. 2G depicts authorities 168 and storage resources in blades 252 of a storage cluster, in accordance with some embodiments. Each authority 168 is exclusively responsible for a partition of the flash 206 and NVRAM 204 on each blade 252. The authority 168 manages the content and integrity of its partitions independently of other authorities 168. Authorities 168 compress incoming data and preserve it temporarily in their NVRAM 204 partitions, and then consolidate, RAID-protect, and persist the data in segments of the storage in their flash 206 partitions. As the authorities 168 write data to flash 206, storage managers 274 perform the necessary flash translation to optimize write performance and maximize media longevity. In the background, authorities 168 “garbage collect,” or reclaim space occupied by data that clients have made obsolete by overwriting the data. It should be appreciated that since authorities' 168 partitions are disjoint, there is no need for distributed locking to execute client and writes or to perform background functions.

The embodiments described herein may utilize various software, communication and/or networking protocols. In addition, the configuration of the hardware and/or software may be adjusted to accommodate various protocols. For example, the embodiments may utilize Active Directory, which is a database based system that provides authentication, directory, policy, and other services in a WINDOWS™ environment. In these embodiments, LDAP (Lightweight Directory Access Protocol) is one example application protocol for querying and modifying items in directory service providers such as Active Directory. In some embodiments, a network lock manager (NLM) is utilized as a facility that works in cooperation with the Network File System (NFS) to provide a System V style of advisory file and record locking over a network. The Server Message Block (SMB) protocol, one version of which is also known as Common Internet File System (CIFS), may be integrated with the storage systems discussed herein. SMP operates as an application-layer network protocol typically used for providing shared access to files, printers, and serial ports and miscellaneous communications between nodes on a network. SMB also provides an authenticated inter-process communication mechanism. AMAZON™ S3 (Simple Storage Service) is a web service offered by Amazon Web Services, and the systems described herein may interface with Amazon S3 through web services interfaces (REST (representational state transfer), SOAP (simple object access protocol), and BitTorrent). A RESTful API (application programming interface) breaks down a transaction to create a series of small modules. Each module addresses a particular underlying part of the transaction. The control or permissions provided with these embodiments, especially for object data, may include utilization of an access control list (ACL). The ACL is a list of permissions attached to an object and the ACL specifies which users or system processes are granted access to objects, as well as what operations are allowed on given objects. The systems may utilize Internet Protocol version 6 (IPv6), as well as IPv4, for the communications protocol that provides an identification and location system for computers on networks and routes traffic across the Internet. The routing of packets between networked systems may include Equal-cost multi-path routing (ECMP), which is a routing strategy where next-hop packet forwarding to a single destination can occur over multiple “best paths” which tie for top place in routing metric calculations. Multi-path routing can be used in conjunction with most routing protocols, because it is a per-hop decision limited to a single router. The software may support Multi-tenancy, which is an architecture in which a single instance of a software application serves multiple customers. Each customer may be referred to as a tenant. Tenants may be given the ability to customize some parts of the application, but may not customize the application's code, in some embodiments. The embodiments may maintain audit logs. An audit log is a document that records an event in a computing system. In addition to documenting what resources were accessed, audit log entries typically include destination and source addresses, a timestamp, and user login information for compliance with various regulations. The embodiments may support various key management policies, such as encryption key rotation. In addition, the system may support dynamic root passwords or some variation dynamically changing passwords.

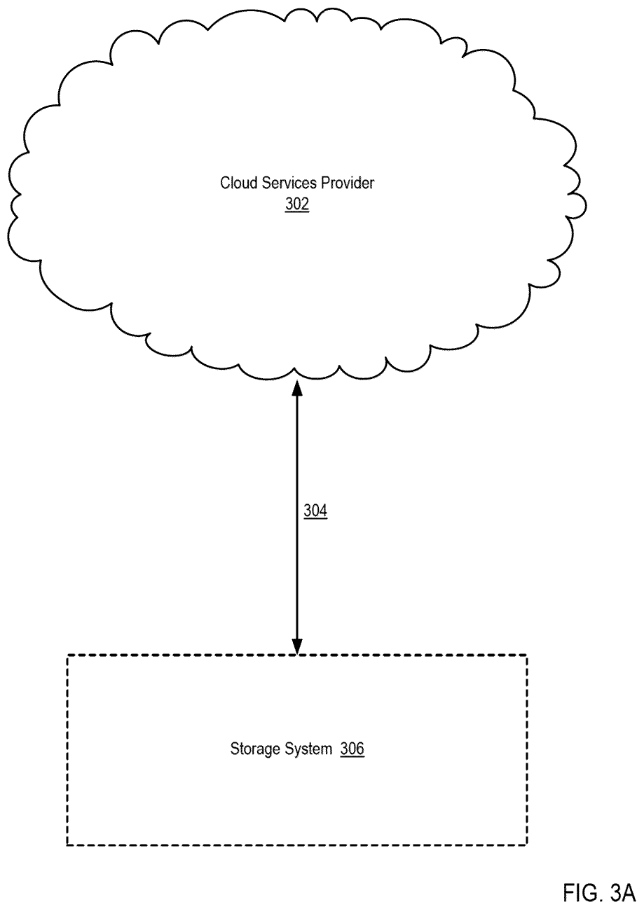

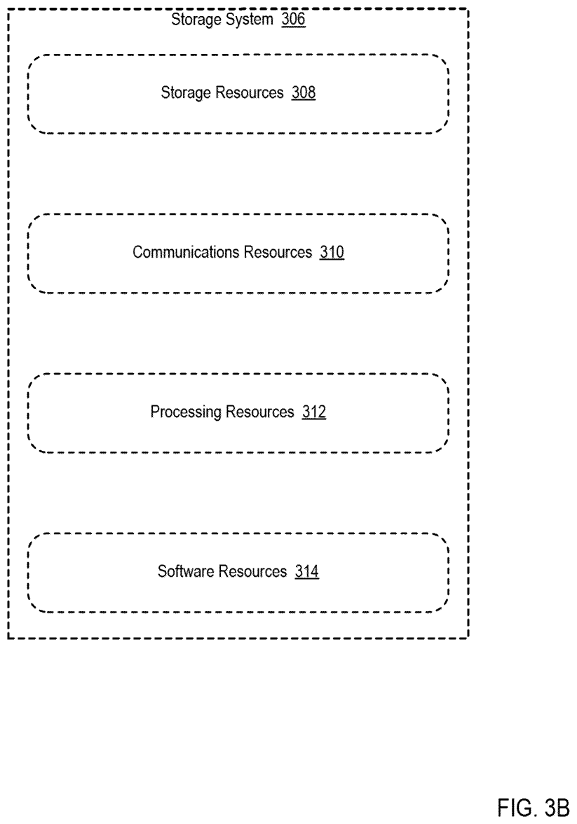

FIG. 3A sets forth a diagram of a storage system 306 that is coupled for data communications with a cloud services provider 302 in accordance with some embodiments of the present disclosure. Although depicted in less detail, the storage system 306 depicted in FIG. 3A may be similar to the storage systems described above with reference to FIGS. 1A-1D and FIGS. 2A-2G. In some embodiments, the storage system 306 depicted in FIG. 3A may be embodied as a storage system that includes imbalanced active/active controllers, as a storage system that includes balanced active/active controllers, as a storage system that includes active/active controllers where less than all of each controller's resources are utilized such that each controller has reserve resources that may be used to support failover, as a storage system that includes fully active/active controllers, as a storage system that includes dataset-segregated controllers, as a storage system that includes dual-layer architectures with front-end controllers and back-end integrated storage controllers, as a storage system that includes scale-out clusters of dual-controller arrays, as well as combinations of such embodiments.

In the example depicted in FIG. 3A, the storage system 306 is coupled to the cloud services provider 302 via a data communications link 304. The data communications link 304 may be embodied as a dedicated data communications link, as a data communications pathway that is provided through the use of one or data communications networks such as a wide area network (‘WAN’) or local area network (‘LAN’), or as some other mechanism capable of transporting digital information between the storage system 306 and the cloud services provider 302. Such a data communications link 304 may be fully wired, fully wireless, or some aggregation of wired and wireless data communications pathways. In such an example, digital information may be exchanged between the storage system 306 and the cloud services provider 302 via the data communications link 304 using one or more data communications protocols. For example, digital information may be exchanged between the storage system 306 and the cloud services provider 302 via the data communications link 304 using the handheld device transfer protocol (‘HDTP’), hypertext transfer protocol (‘HTTP’), internet protocol (‘IP’), real-time transfer protocol (‘RTP’), transmission control protocol (‘TCP’), user datagram protocol (‘UDP’), wireless application protocol (‘WAP’), or other protocol.

The cloud services provider 302 depicted in FIG. 3A may be embodied, for example, as a system and computing environment that provides services to users of the cloud services provider 302 through the sharing of computing resources via the data communications link 304. The cloud services provider 302 may provide on-demand access to a shared pool of configurable computing resources such as computer networks, servers, storage, applications and services, and so on. The shared pool of configurable resources may be rapidly provisioned and released to a user of the cloud services provider 302 with minimal management effort. Generally, the user of the cloud services provider 302 is unaware of the exact computing resources utilized by the cloud services provider 302 to provide the services. Although in many cases such a cloud services provider 302 may be accessible via the Internet, readers of skill in the art will recognize that any system that abstracts the use of shared resources to provide services to a user through any data communications link may be considered a cloud services provider 302.

In the example depicted in FIG. 3A, the cloud services provider 302 may be configured to provide a variety of services to the storage system 306 and users of the storage system 306 through the implementation of various service models. For example, the cloud services provider 302 may be configured to provide services to the storage system 306 and users of the storage system 306 through the implementation of an infrastructure as a service (‘IaaS’) service model where the cloud services provider 302 offers computing infrastructure such as virtual machines and other resources as a service to subscribers. In addition, the cloud services provider 302 may be configured to provide services to the storage system 306 and users of the storage system 306 through the implementation of a platform as a service (‘PaaS’) service model where the cloud services provider 302 offers a development environment to application developers. Such a development environment may include, for example, an operating system, programming-language execution environment, database, web server, or other components that may be utilized by application developers to develop and run software solutions on a cloud platform. Furthermore, the cloud services provider 302 may be configured to provide services to the storage system 306 and users of the storage system 306 through the implementation of a software as a service (‘SaaS’) service model where the cloud services provider 302 offers application software, databases, as well as the platforms that are used to run the applications to the storage system 306 and users of the storage system 306, providing the storage system 306 and users of the storage system 306 with on-demand software and eliminating the need to install and run the application on local computers, which may simplify maintenance and support of the application. The cloud services provider 302 may be further configured to provide services to the storage system 306 and users of the storage system 306 through the implementation of an authentication as a service (‘AaaS’) service model where the cloud services provider 302 offers authentication services that can be used to secure access to applications, data sources, or other resources. The cloud services provider 302 may also be configured to provide services to the storage system 306 and users of the storage system 306 through the implementation of a storage as a service model where the cloud services provider 302 offers access to its storage infrastructure for use by the storage system 306 and users of the storage system 306. Readers will appreciate that the cloud services provider 302 may be configured to provide additional services to the storage system 306 and users of the storage system 306 through the implementation of additional service models, as the service models described above are included only for explanatory purposes and in no way represent a limitation of the services that may be offered by the cloud services provider 302 or a limitation as to the service models that may be implemented by the cloud services provider 302.

In the example depicted in FIG. 3A, the cloud services provider 302 may be embodied, for example, as a private cloud, as a public cloud, or as a combination of a private cloud and public cloud. In an embodiment in which the cloud services provider 302 is embodied as a private cloud, the cloud services provider 302 may be dedicated to providing services to a single organization rather than providing services to multiple organizations. In an embodiment where the cloud services provider 302 is embodied as a public cloud, the cloud services provider 302 may provide services to multiple organizations. Public cloud and private cloud deployment models may differ and may come with various advantages and disadvantages. For example, because a public cloud deployment involves the sharing of a computing infrastructure across different organization, such a deployment may not be ideal for organizations with security concerns, mission-critical workloads, uptime requirements demands, and so on. While a private cloud deployment can address some of these issues, a private cloud deployment may require on-premises staff to manage the private cloud. In still alternative embodiments, the cloud services provider 302 may be embodied as a mix of a private and public cloud services with a hybrid cloud deployment.

Although not explicitly depicted in FIG. 3A, readers will appreciate that additional hardware components and additional software components may be necessary to facilitate the delivery of cloud services to the storage system 306 and users of the storage system 306. For example, the storage system 306 may be coupled to (or even include) a cloud storage gateway. Such a cloud storage gateway may be embodied, for example, as hardware-based or software-based appliance that is located on premises with the storage system 306. Such a cloud storage gateway may operate as a bridge between local applications that are executing on the storage array 306 and remote, cloud-based storage that is utilized by the storage array 306. Through the use of a cloud storage gateway, organizations may move primary iSCSI or NAS to the cloud services provider 302, thereby enabling the organization to save space on their on-premises storage systems. Such a cloud storage gateway may be configured to emulate a disk array, a block-based device, a file server, or other storage system that can translate the SCSI commands, file server commands, or other appropriate command into REST-space protocols that facilitate communications with the cloud services provider 302.

In order to enable the storage system 306 and users of the storage system 306 to make use of the services provided by the cloud services provider 302, a cloud migration process may take place during which data, applications, or other elements from an organization's local systems (or even from another cloud environment) are moved to the cloud services provider 302. In order to successfully migrate data, applications, or other elements to the cloud services provider's 302 environment, middleware such as a cloud migration tool may be utilized to bridge gaps between the cloud services provider's 302 environment and an organization's environment. Such cloud migration tools may also be configured to address potentially high network costs and long transfer times associated with migrating large volumes of data to the cloud services provider 302, as well as addressing security concerns associated with sensitive data to the cloud services provider 302 over data communications networks. In order to further enable the storage system 306 and users of the storage system 306 to make use of the services provided by the cloud services provider 302, a cloud orchestrator may also be used to arrange and coordinate automated tasks in pursuit of creating a consolidated process or workflow. Such a cloud orchestrator may perform tasks such as configuring various components, whether those components are cloud components or on-premises components, as well as managing the interconnections between such components. The cloud orchestrator can simplify the inter-component communication and connections to ensure that links are correctly configured and maintained.

In the example depicted in FIG. 3A, and as described briefly above, the cloud services provider 302 may be configured to provide services to the storage system 306 and users of the storage system 306 through the usage of a SaaS service model where the cloud services provider 302 offers application software, databases, as well as the platforms that are used to run the applications to the storage system 306 and users of the storage system 306, providing the storage system 306 and users of the storage system 306 with on-demand software and eliminating the need to install and run the application on local computers, which may simplify maintenance and support of the application. Such applications may take many forms in accordance with various embodiments of the present disclosure. For example, the cloud services provider 302 may be configured to provide access to data analytics applications to the storage system 306 and users of the storage system 306. Such data analytics applications may be configured, for example, to receive telemetry data phoned home by the storage system 306. Such telemetry data may describe various operating characteristics of the storage system 306 and may be analyzed, for example, to determine the health of the storage system 306, to identify workloads that are executing on the storage system 306, to predict when the storage system 306 will run out of various resources, to recommend configuration changes, hardware or software upgrades, workflow migrations, or other actions that may improve the operation of the storage system 306.

The cloud services provider 302 may also be configured to provide access to virtualized computing environments to the storage system 306 and users of the storage system 306. Such virtualized computing environments may be embodied, for example, as a virtual machine or other virtualized computer hardware platforms, virtual storage devices, virtualized computer network resources, and so on. Examples of such virtualized environments can include virtual machines that are created to emulate an actual computer, virtualized desktop environments that separate a logical desktop from a physical machine, virtualized file systems that allow uniform access to different types of concrete file systems, and many others.

For further explanation, FIG. 3B sets forth a diagram of a storage system 306 in accordance with some embodiments of the present disclosure. Although depicted in less detail, the storage system 306 depicted in FIG. 3B may be similar to the storage systems described above with reference to FIGS. 1A-1D and FIGS. 2A-2G as the storage system may include many of the components described above.

The storage system 306 depicted in FIG. 3B may include storage resources 308, which may be embodied in many forms. For example, in some embodiments the storage resources 308 can include nano-RAM or another form of nonvolatile random access memory that utilizes carbon nanotubes deposited on a substrate. In some embodiments, the storage resources 308 may include 3D crosspoint non-volatile memory in which bit storage is based on a change of bulk resistance, in conjunction with a stackable cross-gridded data access array. In some embodiments, the storage resources 308 may include flash memory, including single-level cell (‘SLC’) NAND flash, multi-level cell (‘MLC’) NAND flash, triple-level cell (‘TLC’) NAND flash, quad-level cell (‘QLC’) NAND flash, and others. In some embodiments, the storage resources 308 may include non-volatile magnetoresistive random-access memory (‘MRAM’), including spin transfer torque (‘STT’) MRAM, in which data is stored through the use of magnetic storage elements. In some embodiments, the example storage resources 308 may include non-volatile phase-change memory (‘PCM’) that may have the ability to hold multiple bits in a single cell as cells can achieve a number of distinct intermediary states. In some embodiments, the storage resources 308 may include quantum memory that allows for the storage and retrieval of photonic quantum information. In some embodiments, the example storage resources 308 may include resistive random-access memory (‘ReRAM’) in which data is stored by changing the resistance across a dielectric solid-state material. In some embodiments, the storage resources 308 may include storage class memory (‘SCM’) in which solid-state nonvolatile memory may be manufactured at a high density using some combination of sub-lithographic patterning techniques, multiple bits per cell, multiple layers of devices, and so on. Readers will appreciate that other forms of computer memories and storage devices may be utilized by the storage systems described above, including DRAM, SRAM, EEPROM, universal memory, and many others. The storage resources 308 depicted in FIG. 3A may be embodied in a variety of form factors, including but not limited to, dual in-line memory modules (‘DIMMs’), non-volatile dual in-line memory modules (‘NVDIMMs’), M.2, U.2, and others.

The example storage system 306 depicted in FIG. 3B may implement a variety of storage architectures. For example, storage systems in accordance with some embodiments of the present disclosure may utilize block storage where data is stored in blocks, and each block essentially acts as an individual hard drive. Storage systems in accordance with some embodiments of the present disclosure may utilize object storage, where data is managed as objects. Each object may include the data itself, a variable amount of metadata, and a globally unique identifier, where object storage can be implemented at multiple levels (e.g., device level, system level, interface level). Storage systems in accordance with some embodiments of the present disclosure utilize file storage in which data is stored in a hierarchical structure. Such data may be saved in files and folders, and presented to both the system storing it and the system retrieving it in the same format.

The example storage system 306 depicted in FIG. 3B may be embodied as a storage system in which additional storage resources can be added through the use of a scale-up model, additional storage resources can be added through the use of a scale-out model, or through some combination thereof. In a scale-up model, additional storage may be added by adding additional storage devices. In a scale-out model, however, additional storage nodes may be added to a cluster of storage nodes, where such storage nodes can include additional processing resources, additional networking resources, and so on.

The storage system 306 depicted in FIG. 3B also includes communications resources 310 that may be useful in facilitating data communications between components within the storage system 306, as well as data communications between the storage system 306 and computing devices that are outside of the storage system 306. The communications resources 310 may be configured to utilize a variety of different protocols and data communication fabrics to facilitate data communications between components within the storage systems as well as computing devices that are outside of the storage system. For example, the communications resources 310 can include fibre channel (‘FC’) technologies such as FC fabrics and FC protocols that can transport SCSI commands over FC networks. The communications resources 310 can also include FC over ethernet (‘FCOE’) technologies through which FC frames are encapsulated and transmitted over Ethernet networks. The communications resources 310 can also include InfiniBand (‘IB’) technologies in which a switched fabric topology is utilized to facilitate transmissions between channel adapters. The communications resources 310 can also include NVM Express (‘NVMe’) technologies and NVMe over fabrics (‘NVMeoF’) technologies through which non-volatile storage media attached via a PCI express (‘PCIe’) bus may be accessed. The communications resources 310 can also include mechanisms for accessing storage resources 308 within the storage system 306 utilizing serial attached SCSI (‘SAS’), serial ATA (‘SATA’) bus interfaces for connecting storage resources 308 within the storage system 306 to host bus adapters within the storage system 306, internet small computer systems interface (‘iSCSI’) technologies to provide block-level access to storage resources 308 within the storage system 306, and other communications resources that may be useful in facilitating data communications between components within the storage system 306, as well as data communications between the storage system 306 and computing devices that are outside of the storage system 306.

The storage system 306 depicted in FIG. 3B also includes processing resources 312 that may be useful in executing computer program instructions and performing other computational tasks within the storage system 306. The processing resources 312 may include one or more application-specific integrated circuits (‘ASICs’) that are customized for some particular purpose as well as one or more central processing units (‘CPUs’). The processing resources 312 may also include one or more digital signal processors (‘DSPs’), one or more field-programmable gate arrays (‘FPGAs’), one or more systems on a chip (‘SoCs’), or other form of processing resources 312. The storage system 306 may utilize the storage resources 312 to perform a variety of tasks including, but not limited to, supporting the execution of software resources 314 that will be described in greater detail below.

The storage system 306 depicted in FIG. 3B also includes software resources 314 that, when executed by processing resources 312 within the storage system 306, may perform various tasks. The software resources 314 may include, for example, one or more modules of computer program instructions that when executed by processing resources 312 within the storage system 306 are useful in carrying out various data protection techniques to preserve the integrity of data that is stored within the storage systems. Readers will appreciate that such data protection techniques may be carried out, for example, by system software executing on computer hardware within the storage system, by a cloud services provider, or in other ways. Such data protection techniques can include, for example, data archiving techniques that cause data that is no longer actively used to be moved to a separate storage device or separate storage system for long-term retention, data backup techniques through which data stored in the storage system may be copied and stored in a distinct location to avoid data loss in the event of equipment failure or some other form of catastrophe with the storage system, data replication techniques through which data stored in the storage system is replicated to another storage system such that the data may be accessible via multiple storage systems, data snapshotting techniques through which the state of data within the storage system is captured at various points in time, data and database cloning techniques through which duplicate copies of data and databases may be created, and other data protection techniques. Through the use of such data protection techniques, business continuity and disaster recovery objectives may be met as a failure of the storage system may not result in the loss of data stored in the storage system.

The software resources 314 may also include software that is useful in implementing software-defined storage (‘SDS’). In such an example, the software resources 314 may include one or more modules of computer program instructions that, when executed, are useful in policy-based provisioning and management of data storage that is independent of the underlying hardware. Such software resources 314 may be useful in implementing storage virtualization to separate the storage hardware from the software that manages the storage hardware.

The software resources 314 may also include software that is useful in facilitating and optimizing I/O operations that are directed to the storage resources 308 in the storage system 306. For example, the software resources 314 may include software modules that perform carry out various data reduction techniques such as, for example, data compression, data deduplication, and others. The software resources 314 may include software modules that intelligently group together I/O operations to facilitate better usage of the underlying storage resource 308, software modules that perform data migration operations to migrate from within a storage system, as well as software modules that perform other functions. Such software resources 314 may be embodied as one or more software containers or in many other ways.

Readers will appreciate that the various components depicted in FIG. 3B may be grouped into one or more optimized computing packages as converged infrastructures. Such converged infrastructures may include pools of computers, storage and networking resources that can be shared by multiple applications and managed in a collective manner using policy-driven processes. Such converged infrastructures may minimize compatibility issues between various components within the storage system 306 while also reducing various costs associated with the establishment and operation of the storage system 306. Such converged infrastructures may be implemented with a converged infrastructure reference architecture, with standalone appliances, with a software driven hyper-converged approach, or in other ways.

Readers will appreciate that the storage system 306 depicted in FIG. 3B may be useful for supporting various types of software applications. For example, the storage system 306 may be useful in supporting artificial intelligence applications, database applications, DevOps projects, electronic design automation tools, event-driven software applications, high performance computing applications, simulation applications, high-speed data capture and analysis applications, machine learning applications, media production applications, media serving applications, picture archiving and communication systems (‘PACS’) applications, software development applications, and many other types of applications by providing storage resources to such applications.

The storage systems described above may operate to support a wide variety of applications. In view of the fact that the storage systems include compute resources, storage resources, and a wide variety of other resources, the storage systems may be well suited to support applications that are resource intensive such as, for example, artificial intelligence applications. Such artificial intelligence applications may enable devices to perceive their environment and take actions that maximize their chance of success at some goal. The storage systems described above may also be well suited to support other types of applications that are resource intensive such as, for example, machine learning applications. Machine learning applications may perform various types of data analysis to automate analytical model building. Using algorithms that iteratively learn from data, machine learning applications can enable computers to learn without being explicitly programmed.

In addition to the resources already described, the storage systems described above may also include graphics processing units (‘GPUs’), occasionally referred to as visual processing unit (‘VPUs’). Such GPUs may be embodied as specialized electronic circuits that rapidly manipulate and alter memory to accelerate the creation of images in a frame buffer intended for output to a display device. Such GPUs may be included within any of the computing devices that are part of the storage systems described above.

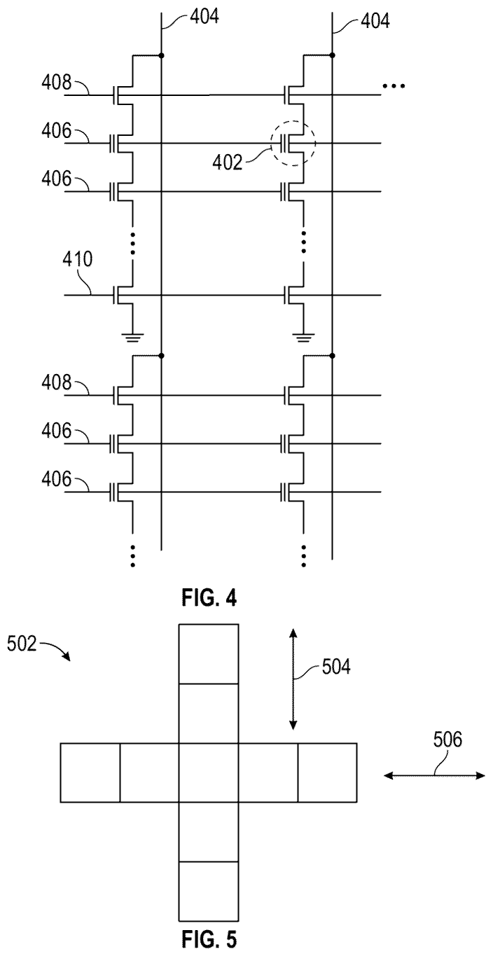

FIG. 4 depicts an example of NAND flash memory structure, showing word lines 406, bit lines 404 and cells 402. The flash memory structure shown herein is for purposes of illustrating flash device-based filling needs and should be considered instructional rather than limiting in embodiments. A typical cell 402 in NAND flash memory includes a metal oxide field effect transistor (MOSFET) that has a floating gate that can take on electrons (typically when a zero is written to the corresponding bit) or have electrons pulled off (typically when an entire block is erased to all ones). Flash cells 402 are arranged in series, with the gate (i.e., control gate, not the floating gate) of each cell 402 connected to a word line 406 and the series connection of cells 402 connected to a bit line 404 in the NAND flash memory. Each word line 406 extends across many cells 402 corresponding to many bit lines 404. Each series-connected set of cells 402 connected to a bit line 404 has many word lines 406, one for each cell 402 in the series stack of cells 402. A ground select line 410 activates a ground connection or ground select MOSFET at one end of the series of cells 402, and a bit select line 408 activates a bit line connection or bit selection MOSFET at the other end of the series of cells 402.

Still referring to FIG. 4, a manufacturer of a NAND flash memory may recommend word lines 406 be filled for best read reliability of the memory, as a device-based filling need/recommendation. This may be interpreted as a recommendation (or requirement) that all of the cells 402 to which a word line 406 is connected should be written to, for as many word lines 406 that have any cell 402 written to, as possible. The manufacturer may specify sets of partner pages to be filled for this recommendation. A manufacturer of a NAND flash memory may recommend multilevel cells be filled for best read reliability of the memory, as a device-based filling need. Similarly, this may be interpreted as a recommendation (or requirement) that all of the bits for a multilevel cell be written (whether zero or one value), for as many multilevel cells that have any bit written to, as possible. The manufacturer may specify sets of pages, e.g., lower page, upper page for two bit multilevel cell, lower page, upper page and extra page for four bit multilevel cell, also known as quad level cell, etc. In various embodiments, writing to specified sets of pages fulfills the device-based filling need. In comparison, writing to a subset of the pages in a given specified set of pages, but not writing to one or more other pages in that specified set of pages, would not fulfill the device-based filling need.

FIG. 5 depicts writing to flash memory in a geometry-aware, two-dimensional parity process to meet flash device-based filling needs. The geometry 502 shown in FIG. 5 has a horizontal 506 set of elements, representing writing data for data stripes that spans flash memory devices. For example, in a storage array or storage cluster, a data stripe is written across solid-state drives, solid-state storage units, solid-state memory in or coupled to storage nodes, etc. The geometry 502 has a vertical 504 set of elements, representing writing bits or pages to fill word lines or multilevel cells, according to a device-based filling need. In the embodiment shown, parity bits or parity pages are written to the vertical 504 set of elements. In further embodiments, data bits or data pages could be written to the vertical 504 set of elements. In still further embodiments, mixed data bits and parity bits or mixed data pages and parity pages could be written to the vertical 504 set of elements.

Elements in the vertical 504 aspect of the geometry 502 of FIG. 5 could thus represent bits and cells 402 along a word line 406, or pages in a page set associated with a word line 406, for a word line filling recommendation or requirement. Alternatively, the elements in the vertical 504 aspect of the geometry 502 could represent bits of a multilevel cell, or pages in a page set associated with a multilevel cell, for a multilevel cell filling recommendation or requirement. Elements in the horizontal 506 aspect of the geometry 502 could represent bits for a data stripe, with parity bits assigned as needed along the vertical 504 aspect and data bits to either side of the vertical 504 aspect, along the horizontal 506 aspect. In some embodiments, the elements in the horizontal 506 aspect of the geometry 502 could represent pages in a data stripe, with parity pages assigned as needed along the vertical 504 aspect and data pages to either side of the vertical 504 aspect, along the horizontal 506 aspect. Other representations of the geometry 502 in the context of other filling recommendations or requirements are readily envisioned.

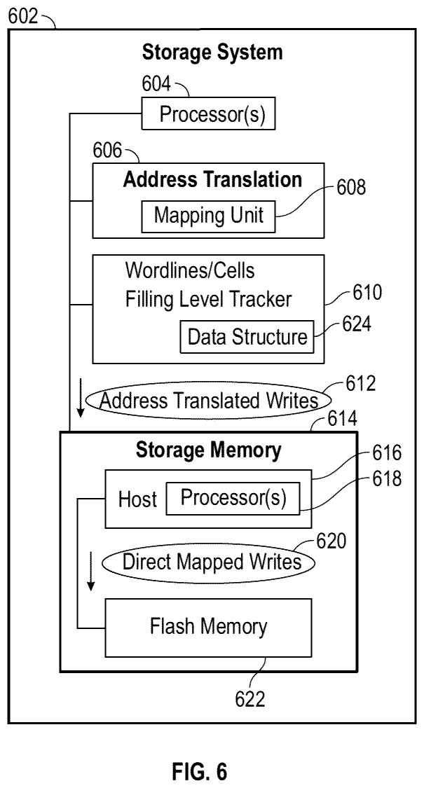

FIG. 6 sets forth an embodiment of a storage system 602 with word lines or cells filling level tracker 610 that employs direct-mapped writes 620 to flash memory 622 and the geometry-aware, two-dimensional parity process of FIG. 5. Various storage systems described with reference to FIGS. 1A-3B, and variations thereof, as well as further storage systems, are candidates for embodiments of the storage system 602. In the storage system 602, one or more processors 604 use an address translation unit 606 with a mapping unit 608 to perform address translated writes 612 to the storage memory 614. Storage memory 614 has a host 616 with one or more processors 618 that perform direct mapped writes 620 into the flash memory 622 of the storage memory 614, as directed by the address translated writes 612 from the processors 604 of the storage system 602.

Continuing with FIG. 6, the word lines or cells filling level tracker 610 has a data structure 624, in some embodiments. In order to track filling levels of word lines or cells, depending on recommendations for the flash memory 622, the word lines or cells filling level tracker 610 could monitor address translated writes 612 and/or direct mapped writes 620, or receive relevant information regarding the address translated writes 612 and/or the direct mapped writes 620 from the processor(s) 604 of the storage system 602 or the processor(s) 618 of the storage memory 614. For example, the filling level tracker 610 could write metadata regarding writes to the bits, pages or blocks, to the data structure 624, and consult the data structure 624 to determine which bits, pages or blocks have not yet fulfilled the filling level needs of the flash memory 622.

The filling level tracker 610 of FIG. 6 could populate the data structure 624 with information about whether pages, blocks, groups of pages or blocks, or the entire flash devices (e.g., integrated circuits, packaged sets of one or more integrated circuits, printed circuit boards, solid-state drives, etc.) have filling needs and whether those filling needs are for word lines versus multilevel cells or both. In some embodiments, such metadata regarding tracked filling levels is combined with other metadata for bits, pages or blocks, for example in cooperation with the address translation unit 606. By keeping page addressing as well as page filling information together in the data structure 624, for example, bookkeeping for the filling level needs could be consolidated with address mapping for used and available addresses. In some embodiments, the address translation unit 606 could otherwise cooperate with the filling level tracker 610 and write parity bits or parity pages for the filling level needs of the flash memory 622 in accordance with an addressing scheme and address translation, and the direct mapped writes 620.

Embodiments of the storage system 602 of FIG. 6 form data stripes, with data bits and parity bits, track occupancy of word lines 406 or multilevel cells and the flash memory 622, and write parity bits or parity pages to fill word lines or multilevel cells in accordance with the occupancy tracking. In some versions, writing to fill the word line or the multilevel cell is on an as-needed basis. For example, data bits or data pages could be written to flash memory 622 for a data stripe, and the parity bits or parity pages held in a pool (e.g., in NVRAM 204, see FIG. 2C, or other type of RAM), then written to selected locations in flash memory 622 when the filling level tracker 610 detects one or more unfilled word lines or multilevel cells, or the tracked filling level meets a threshold.

In some versions, writing to fill the word line or the multilevel cell is on an as-available basis. For example, the filling level tracker 610 could identify unfilled word lines or multilevel cells, and then when parity bits or parity pages become available, for example meeting a threshold level, the storage system 602 could write those parity bits or parity pages to fill the indicated word line(s) or multilevel cell(s). In some versions, if parity bits or parity pages are unavailable, the storage system 602 could write non-valid data (i.e., junk data, filler data) to fill the indicated word line(s) or multilevel cell(s). Also in some embodiments, some of the parity bits or parity pages are written to available locations in flash memory or to fulfill other storage system needs such as efficient use of storage space, while other parity bits are parity pages are written to satisfy word line or multilevel cell filling needs.

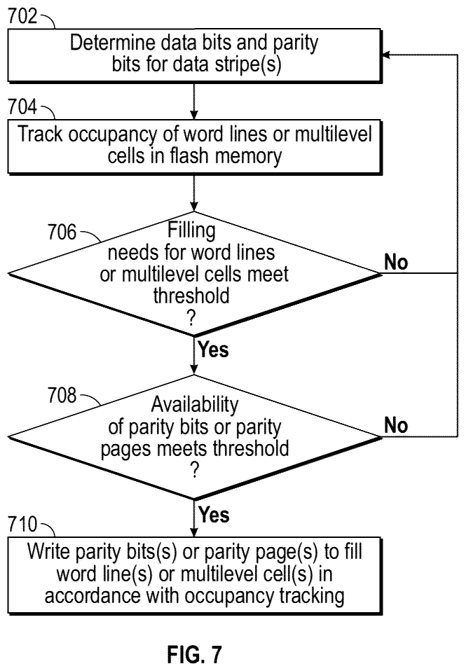

FIG. 7 is a flow diagram of a method of geometry-aware parity writing, which can be performed by storage systems described herein, and further storage systems. The method can be practiced by one or more processors of a storage system. In an action 702, data bits and parity bits are determined for one or more data stripes. In an action 704, occupancy of word lines or multilevel cells and flash memory is tracked. In various embodiments, the storage system tracks writes to bits, pages or blocks through address translation and/or direct-mapped writing from a host, writing metadata to a data structure. This could be relative to or compared to recommended page sets from a manufacturer in some embodiments.

In a determination action 706, it is determined whether the filling needs for word lines or multilevel cells in the flash memory meet a threshold. If the answer is no, the filling needs do not meet a threshold, flow branches back to the action 702 (and action 704) in order to continue forming data stripes and tracking occupancy of word lines or multilevel cells. If the answer is yes, the filling needs meet the threshold, flow proceeds to the determination action 708. In the determination action 708, it is determined whether the availability of parity bits or parity pages meets a threshold. If the answer is no, the availability of parity bits or parity pages does not meet the threshold, flow branches back to the action 702 (and action 704) in order to continue forming data stripes and tracking occupancy of word lines or multilevel cells. If the answer is yes, the availability of parity bits or parity pages meets the threshold, flow proceeds to the action 710.

In the action 710 of FIG. 7, one or more parity bits or one or more parity pages are written to fill one or more word lines or one or more multilevel cells, in accordance with the occupancy tracking. Filling word lines or multilevel cells according to relevant manufacturer and flash memory recommendations improves reliability of reads of the flash memory. In variations of the method, actions could be performed in a different order or in parallel, e.g. through multithreaded or multiprocessor operations. One or both of determination actions 706 and 708 could be omitted in a system that does not test availability or demand in some embodiments. Further variations are readily devised in keeping with the teachings herein.

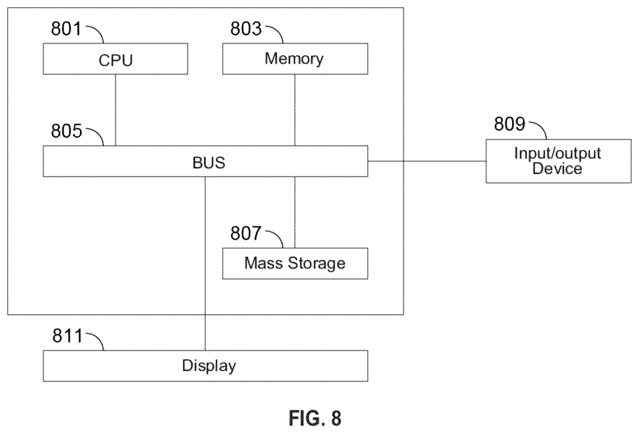

It should be appreciated that the methods described herein may be performed with a digital processing system, such as a conventional, general-purpose computer system. Special purpose computers, which are designed or programmed to perform only one function may be used in the alternative. FIG. 8 is an illustration showing an exemplary computing device which may implement the embodiments described herein. The computing device of FIG. 8 may be used to perform embodiments of the functionality for filling word lines or multilevel cells in accordance with some embodiments. The computing device includes a central processing unit (CPU) 801, which is coupled through a bus 805 to a memory 803, and mass storage device 807. Mass storage device 807 represents a persistent data storage device such as a disc drive, which may be local or remote in some embodiments. The mass storage device 807 could implement a backup storage, in some embodiments. Memory 803 may include read only memory, random access memory, etc. Applications resident on the computing device may be stored on or accessed via a computer readable medium such as memory 803 or mass storage device 807 in some embodiments. Applications may also be in the form of modulated electronic signals modulated accessed via a network modem or other network interface of the computing device. It should be appreciated that CPU 801 may be embodied in a general-purpose processor, a special purpose processor, or a specially programmed logic device in some embodiments.

Display 811 is in communication with CPU 801, memory 803, and mass storage device 807, through bus 805. Display 811 is configured to display any visualization tools or reports associated with the system described herein. Input/output device 809 is coupled to bus 805 in order to communicate information in command selections to CPU 801. It should be appreciated that data to and from external devices may be communicated through the input/output device 809. CPU 801 can be defined to execute the functionality described herein to enable the functionality described with reference to FIGS. 1A-7. The code embodying this functionality may be stored within memory 803 or mass storage device 807 for execution by a processor such as CPU 801 in some embodiments. The operating system on the computing device may be MS-WINDOWS™, UNIX™, LINUX™, iOS™, CentOS™, Android™, Redhat Linux™, z/OS™, or other known operating systems. It should be appreciated that the embodiments described herein may also be integrated with a virtualized computing system implemented with physical computing resources.

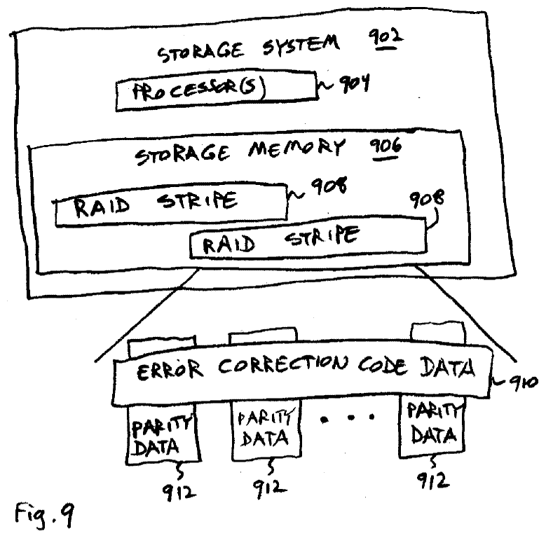

FIG. 9 depicts a storage system 902 with RAID stripes 908 in storage memory 906, showing error correction code (ECC) data 910 and parity data 912 for the error correction code data 910. The type of ECC to use in a given storage system 902, and architecture of the storage system 902, are design choices specific to a system. Depending on the type of ECC, a storage system 902 can detect and correct a specified number of errors in a RAID stripe 908 in some embodiments. For example, an embodiment of the storage system 902 could detect and correct errors resulting from a loss of up to two drives in a storage array, two storage nodes 150 or two storage units 152 in a storage cluster 161, or two bits in a data word, with appropriate ECC. Although ECC data 910 may be self-sufficient without parity data 912, having parity data 912 for and distinct from the ECC data 910 further improves system reliability. Parity data 912 can detect errors in the ECC data 910, and may be used to detect situations where there is a larger number of errors in a data word or RAID stripe 908 than can be detected or corrected by the ECC data 910. Particularly, parity data 912 can detect situations that could result in a mis-corrected data word from the ECC data 910, for example where there are a larger number of errors but some of the errors work to mis-correct other errors in an ECC scheme. Parity data 912 can also detect page failures and block failures, which the storage system 902 could then test and restore, report or retire, in some embodiments.

Continuing with FIG. 9, one risk that is identified is that parity data 912 can be subject to the same kinds of failures as any of the ECC data 910. A failure that affects ECC data 910 and associated parity data 912 renders the parity data 912 less useful or effective in detecting the failure of the ECC data 910 itself. Thus, to improve system reliability, various embodiments described below move sections of the parity data 912 to physical locations in storage memory that are less likely to be affected at the same time and by the same failure as the specific error correction code data 910 to which a given section of parity data 912 is associated. There are various failure mechanisms for storage memory 906, and various ways and locations for placement of parity data 912 that can compensate for the failure mechanisms in a configurable, geometry-aware parity feature that is applicable to direct mapped flash memory in a storage system 902.

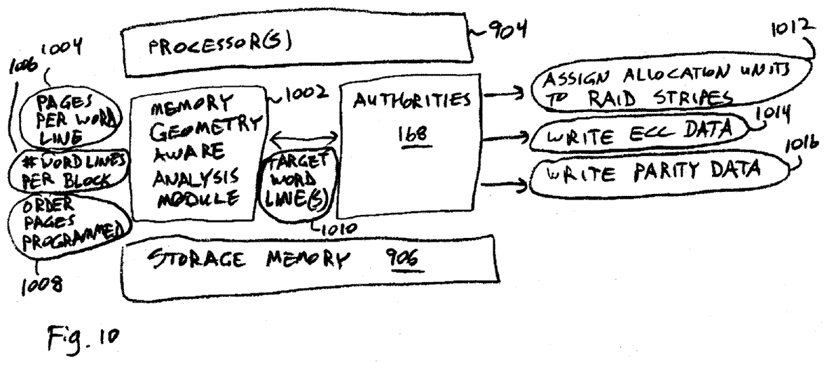

FIG. 10 depicts an embodiment of a storage system 902 with a memory geometry aware analysis module 1002 in cooperation with authorities 168, writing error correction code data 910 and parity data 912. The memory geometry aware analysis module 1002, implemented in software executing on one or more processors 904, hardware, firmware, or combinations thereof, could also be implemented with other processor(s) 904 in other storage systems 902 in further embodiments. Geometry aware may refer to the feature that the storage system 902 has information about failure mechanisms, such as their existence, probabilities, and physical locations relative to addressing schemes, and can perform analysis and make decisions about where to locate data for improved reliability, using geometry awareness.

In the embodiment shown in FIG. 10, authorities 168 own ranges of user data and associated metadata, and make decisions about error correction coding and locations for where to write data and metadata for the data they own. In other types of storage systems 902, these decisions and data accesses could be performed by other processor(s) 904 in storage arrays and storage clusters, etc. The memory geometry aware analysis module 1002 has information about the number of pages per word line 1004, the number of word lines per block 1006, the order in which pages are programmed 1008, and/or other aspects of memory geometry in the context of failure mechanisms and physical locations in address space(s) for the storage memory 906. With this information and cooperation, the authorities 168 and the memory geometry aware analysis module 1002 identify and select target word line(s) 1010, target pages, target blocks, target logical unit numbers (LUNs) or other target regions for data writes. Authorities 168 assign allocation units to RAID stripes 1012, write ECC data 1014, and write parity data 1016 to target locations as identified and selected, among other tasks.

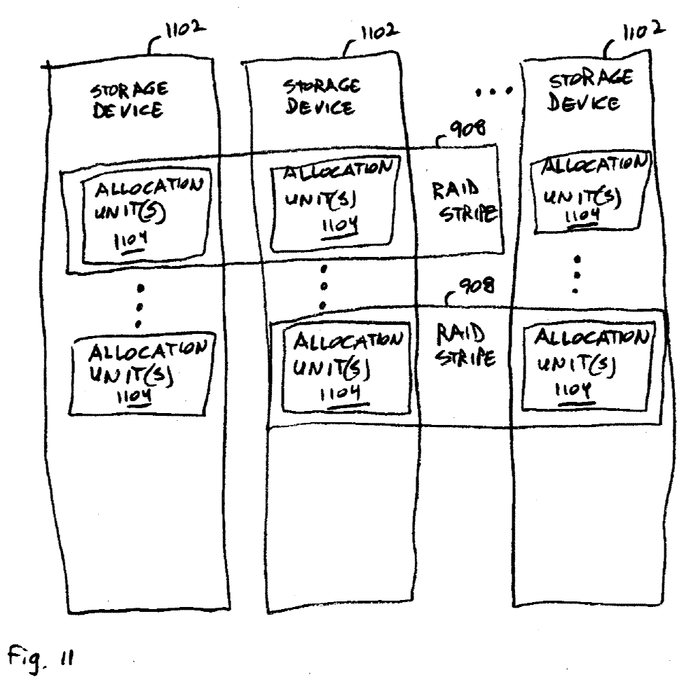

FIG. 11 illustrates allocation units 1104 of storage memory 906 in RAID stripes 908. Various embodiments of storage systems 902 could establish RAID stripes 908 that have one allocation unit 1104 per storage device 1102 (e.g., solid-state drive, storage node 150, storage unit 152, etc.) over a subset or all of the storage devices 1102 of the storage system 902, or RAID stripes 908 that are taller than one allocation unit 1104. For each allocation unit in a RAID stripe 908, the memory geometry aware analysis module 1002 (of FIG. 10) determines or assists in determining where to write the parity data 912. Other embodiments of storage systems 902 may use other mechanisms for memory allocation, and suitable related processes for determining locations for parity data 912 relative to those memory allocations, using geometry awareness, are readily devised in accordance with the teachings herein.

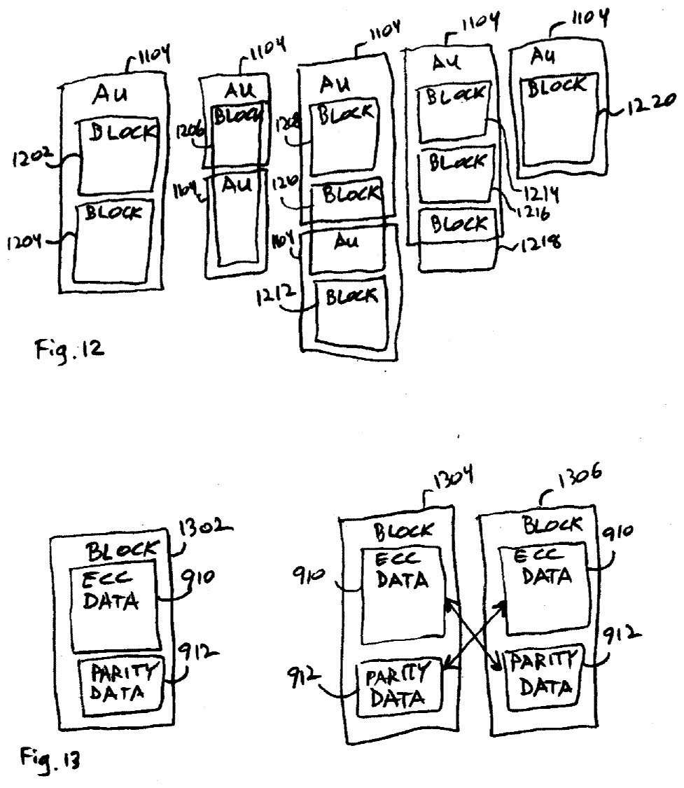

FIG. 12 depicts heterogeneous block sizes, allocation unit sizes and block membership in allocation units in embodiments of storage memory. Allocation units in a homogeneous storage memory 906 could all conform to one of these examples, and in a heterogeneous storage memory 906 could conform to two or more of these examples, or variations thereof. In all of these cases, embodiments of the storage system 902 with a memory geometry aware analysis module 1002 place parity data for the blocks of the allocation units to improve reliability. One allocation unit 1104 has two blocks 1202, 1204 of solid-state storage memory. In another example, two allocation units 1104 share a block 1206, so that each allocation unit 1104 has half a block 1206, or other portion of a block. Two allocation units 1104 share three blocks 1208, 1210, 1212 in yet another example, so that each allocation unit 1104 has one and a half blocks. In one example, an allocation unit 1104 has two and a half blocks 1214, 1216, 1218. In one embodiment, an allocation unit 1104 is made up of exactly one block 1220. Other proportions of blocks and allocation units are readily envisioned, and memory of heterogeneous block sizes and/or heterogeneous allocation unit sizes is possible in various embodiments of the storage system 902.

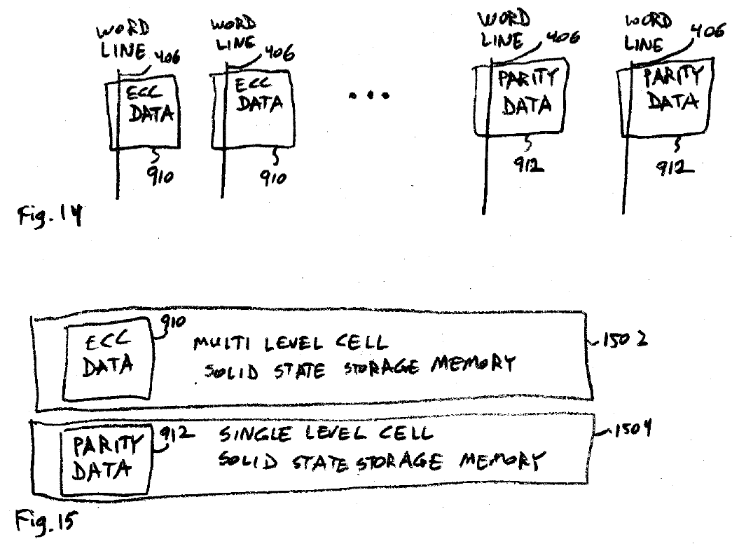

FIG. 13 illustrates locations of parity data 912 for the error correction code data 910, as arranged by the storage systems 902 depicted in FIGS. 9 and 10. In one embodiment, the storage system 902 writes the parity data 912 for the ECC data 910 of a block 1302 to another location in the same block 1302. For example, the storage system 902 selects the physical location through addressing and geometry awareness so that a piece of ECC data 910 and the parity data 912 for that specific piece of ECC data 910 are less likely to be affected by a specific failure (see, e.g., FIGS. 14 and 15).

In one embodiment, the storage system 902 writes the parity data 912 for the ECC data 910 in a block 1304 to another, different block 1306. If the block 1304 fails, the parity data 912 in the other block 1306 may survive, and vice versa. An arrangement could be made with paired blocks 1304, 1306, and the parity data 912 for the ECC data 910 in the other block 1306 written to the first block 1304. Alternatively, selection of which block is used for writing parity data 912 could be randomized or based on other criteria, rather than taking place with paired blocks 1304, 1306 as shown in the right side of FIG. 13.

FIG. 14 depicts error correction code data 910 and parity data 912 written along various word lines 406 in storage memory. Locating parity data 912 on a different word line 406 than the ECC data 910 gives a survivability advantage to the parity data 912 in case of a word line 406 failure affecting the ECC data 910. In some embodiments, parity data 912 is placed along a single word line 406 that is not used by any of the ECC data 910, or along multiple word lines 406 in a block 1302 (see FIG. 13). Strategies can even be combined, with parity data 912 placed along word lines 406 not used by ECC data 910, in different blocks 1306 than the ECC data 910 to which the parity data 912 corresponds.

FIG. 15 depicts error correction code data 910 and parity data 912 written to different types of solid-state storage memory. In this example, the ECC data 910 is written to multilevel cell solid-state storage memory 1502, and the parity data 912 is written to single level cell solid-state storage memory 1504, or multilevel cell memory that has fewer bits per cell than the multilevel cell memory to which the ECC data 910 is written (e.g., two bits per cell versus three or four bits per cell, etc.) Single level cell (SLC) flash memory generally has a lower error rate than two bits per cell multilevel cell (MLC) flash memory, which in turn has a lower error rate than three bits per cell MLC, a.k.a. triple level cell (TLC) flash memory, which in turn has a lower error rate than four bits per cell MLC, a.k.a. quad level cell (QLC) flash memory. Embodiments of the storage system 902 can take advantage of these differences in reliability, and write the parity data 912 to the more reliable type of solid-state storage memory for better survivability likelihood of the parity data 912. As above, this strategy can be combined with other strategies for geometry aware parity data placement.

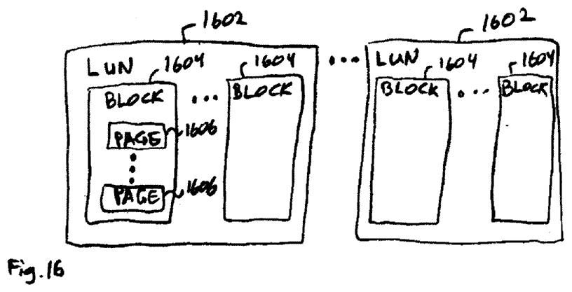

FIG. 16 depicts the hierarchy of logical unit numbers (LUN) 1602, blocks 1604 and pages 1606 in embodiments of solid-state storage memory. The geometry aware storage system 902 could write ECC data 910 and associated parity data 912 to different LUNs 1602, different blocks 1604 in the same LUN 1602, or different blocks 1604 in different LUNs 1602, pages 1606 in different blocks 1604 in the same LUN 1602, or pages 1606 in different blocks 1604 in different LUNs, etc., to improve survivability likelihood of the parity data 912 relative to a failure affecting ECC data 910.

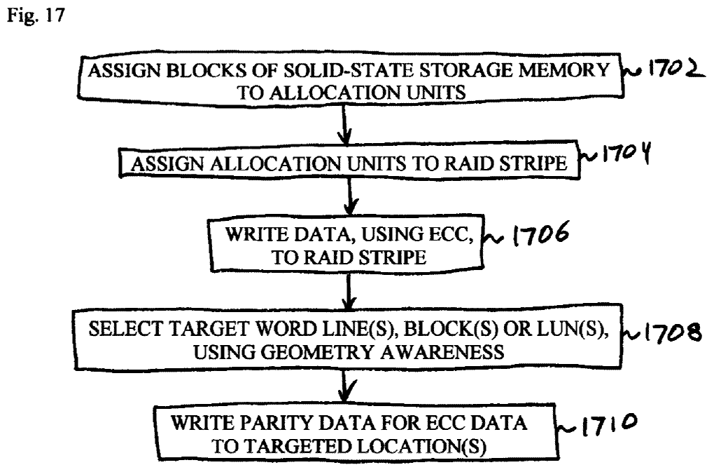

FIG. 17 is a flow diagram of a geometry-aware method of writing parity in a storage system. The method can be practiced by various embodiments of storage systems described herein, and more specifically by one or more processors of a storage system. Actions of generating ECC data and generating parity are not described explicitly in this flow diagram, but are readily understood in keeping with further teachings herein. In an action 1702, blocks of solid-state storage memory are assigned to allocation units. Examples of possible block assignments for homogeneous and heterogeneous embodiments of storage memory are shown in FIG. 12 for embodiments that use allocation units, and storage systems that do not use allocation units may omit this action.

In an action 1704, allocation units are assigned to a RAID stripe. Examples of allocation units and RAID stripes are shown in FIG. 11 for embodiments the use allocation units, and storage systems that do not use allocation units may assign blocks or other amounts of storage memory to RAID stripes. In an action 1706, data is written, using ECC, to the RAID stripe. The error correction coding supports detection and correction of a specified number of errors in the RAID stripe.

In an action 1708, target word line(s), block(s) or LUN(s) are selected, using geometry awareness. The physical location(s) in storage memory, for writing the parity data, are targeted based on where the ECC data is written and probabilities for various types of failures, in combination with the goal of making the parity data more likely to survive a failure that affects some portion of ECC data in a RAID stripe. In an action 1710, the parity data for the ECC data is written to the targeted location(s). Reliability of the storage system, in terms of likelihood of detecting and correcting errors, or detecting mis-corrected errors, is thus improved in comparison to writing parity data for ECC data in location(s) where a single failure could affect both the parity data and the ECC data to which the parity data corresponds.

In some embodiments, performance characteristics of the storage devices of a storage system may be used to intelligently allocate storage devices when forming a RAID group (also referred to as “RAID stripe” hereafter). When a RAID group is formed, different storage devices may have different levels of expected performance. For example, a storage device may be intrinsically slower, either by design or from internal issues; a storage device may contain more data but is not proportionately faster; or a storage device contains data that is expected to be more actively used.

Embodiments of the disclosure provide for an improved storage system by placing parity and/or global parity, which are generally used less frequently, on these lower performance storage devices and placing data, such as user data, on higher performance storage devices. Using the performance characteristics to allocate storage devices may be particularly important for local recover codes (LRCs), since local parity storage devices may only be used for reconstruction of data and global parity storage devices are used even more rarely. Furthermore, as RAID stripes that use LRCs become wider (e.g., written across more storage devices), the number of storage devices of the RAID stripe that store parity increases.

In embodiments, processing logic of a processing device of a storage system controller may perform one or more calculations using corresponding performance characteristics of storage devices of the storage system. In embodiments, the results of the calculation may be a numerical representation of a performance level of a particular storage device of the storage system. For example, a first storage device having corresponding results that are higher than the corresponding results of a second storage device may be indicative of the first storage device having better performance than the second storage device.

The processing logic may use the results of the calculations to determine which storage devices should store data of a RAID stripe, which storage devices should store parity for the RAID stripe, and/or which storage devices should store global parity. The processing logic may then allocate one or more storage devices of the storage system for storing the data, parity, and/or global parity based upon the determination. By factoring in performance characteristics when allocating storage devices for storage of a RAID stripe, data of the RAID stripe may be stored at higher performance storage devices, reducing the latency and increasing the performance of the storage system.

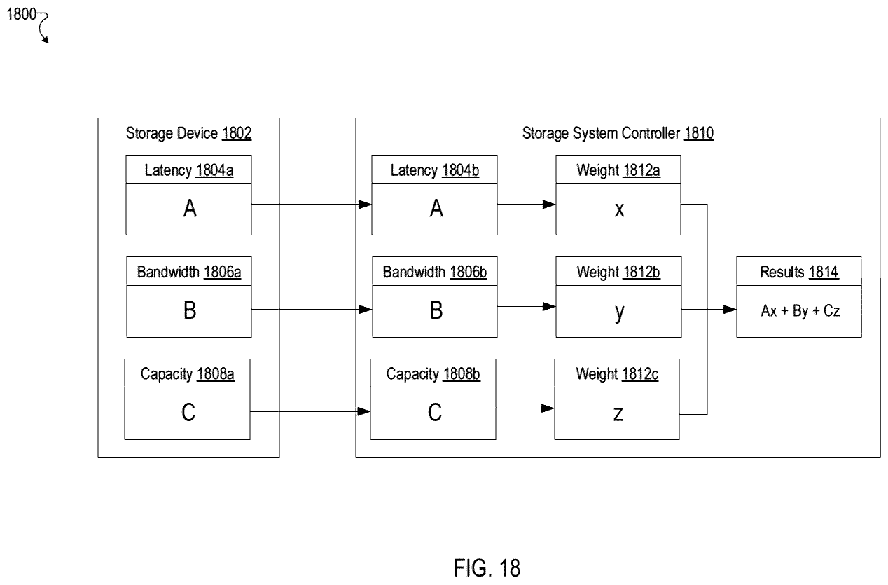

FIG. 18 is an illustration of an example of a storage system controller of a storage system 1800 performing a calculation using performance characteristics of a storage device, in accordance with embodiments of the disclosure. Storage system 1800 may correspond to any of the storage systems previously described. For clarity, some components of storage system 1800 have been omitted. Storage system 1800 includes a storage device 1802 that is operatively coupled to storage system controller 1810.

Storage device 1802 may have corresponding performance characteristics latency 1804a, bandwidth 1806a, and capacity 1808a. Latency 1804a may correspond to an amount of time that elapses for storage device 1802 to access data after receiving an instruction. The bandwidth 1806a may correspond to the maximum rate of data transfer for storage device 1802. The capacity 1808a may correspond to the capacity of storage device 1802 that is available for the storage of data. It should be noted that embodiments of the disclosure may include other performance characteristics in addition to or instead of latency 1804a, bandwidth 1806a, and capacity 1808a. Furthermore, it should be noted that latency 1804a, bandwidth 1806a, and capacity 1808a are shown for illustrative purposes only and are not physical components of storage device 1802.

Referring to FIG. 18, storage device 1802 may provide one or more performance characteristics to the storage system controller 1810 which may be stored in memory (not shown) accessible by storage system controller 1810 as latency 1804b, bandwidth 1806b, and capacity 1808b, which are represented as values A, B, and C, respectively. In embodiments, the storage system controller 1810 may receive some or all of the performance characteristics from a different data source, such as a database or server that maintains performance characteristics of storage devices and components of a storage system, rather than receiving the performance characteristics from storage device 1802. In some embodiments, one or more of the performance characteristics may be provided to the storage system controller 1810 during a system setup and configuration or when storage device 1802 is added to storage system 1800.

In some embodiments, when performing a calculation using the performance statistics of storage device 1802, the storage system controller 1810 may apply weights (e.g., weights 1812a-c) to one or more of the performance characteristics. Weights 1812a-c may be used to increase or decrease the impact of a particular performance characteristic on the results of the calculation relative to the other performance characteristics of the storage device 1802. In FIG. 18, weight 1812a is represented as value x, weight 1812b is represented as value y, and weight 1812c is represented as value z.

The storage system controller 1810 may perform a calculation using the performance characteristics and corresponding weights to produce results 1814, which may be a numerical representation of the performance level of storage device 1802. Results 1814 may be calculated by adding the values of the latency 1804b multiplied by weight 1812a (e.g., Ax), bandwidth 1806b by weight 1812b (e.g., By), and capacity 1808b by weight 1812c (e.g., Cz). It should be noted that the calculation described in FIG. 18 is shown for illustrative purposes only and embodiments of the disclosure may utilize alternative formulas, characteristics, weights, etc., for analyzing the performance of storage devices of a storage system.

In some embodiments, the storage system controller 1810 may execute a machine learning model that may adjust the weights and/or perform the calculations for storage devices of the storage system. For example, over time the machine learning model may determine that the latency characteristic has a greater impact on a storage device's performance than the bandwidth characteristic. Based on this determination, the machine learning model may increase the weight applied to the latency and/or decrease the weight applied to the bandwidth.

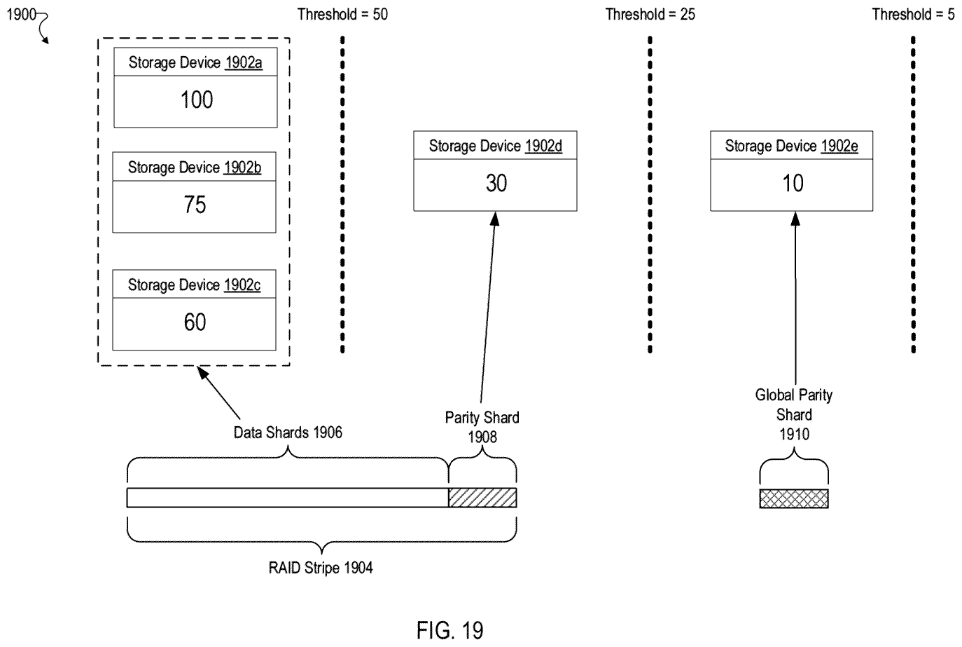

FIG. 19 is an illustration 1900 of an example of a storage system controller allocating storage devices of a storage system for storing data based on results of a calculation, in accordance with embodiments of the disclosure. Illustration 1900 includes storage devices 1902a-e, which may correspond to storage devices of one or more storage systems previously described. Storage devices 1902a-e may each have corresponding calculation results, as previously described in FIG. 18.

Referring to FIG. 19, a storage system controller (not shown) may allocate storage devices of a storage system for the storage of shards of data from a RAID stripe 1904 and/or the storage of global parity 1910. RAID stripe 1904 may include data shards 1906 and one or more parity shards 1908. Data shards 1906 may correspond to data, such as user data, that is to be stored at one or more storage devices of the storage system. Parity shards 1908 may include parity data that may be used to rebuild one or more of data shards 1906 in the event of a failure of one or more of the storage devices storing data shards 1906. Global parity shards 1910 may include global parity data that is calculated using data across multiple RAID stripes of the storage system.

In embodiments, the storage system controller may utilize one or more thresholds for determining which storage devices are to store data shards 1906, which storage devices are to store parity shards 1908, which storage devices are to store global parity shards 1910, and which storage devices are not to be used for storing data, parity, and/or global parity. In FIG. 19, the storage system controller may have a first threshold set at a value of 50 and a second threshold set at a value of 25. Storage devices having corresponding results of the calculation that are above the first threshold value of 50 may be considered as being higher performance and should be allocated for the storage of data shards 1906. Storage devices having corresponding results that are below the first threshold value of 50 and higher than the second threshold value of 25 may be considered as lower performance and should be allocated for the storage of parity shards 1908. Storage devices having corresponding results that are less than the second threshold of 25 may be considered as an even lower performance and should be allocated for the storage of global parity shards 1910.

In FIG. 19, storage device 1902a has a corresponding result of 100, storage device 1902b has a corresponding result of 75, and storage device 1902c has a corresponding result of 60. Because storage devices 1902a-c all have corresponding results that are greater than the first threshold value of 50, the storage system controller may allocate storage devices 1902a-c for the storage of data shards 1906.

Storage device 1902d has a corresponding result of 30. Because storage device 1902d has a corresponding result that is below the first threshold value of 50, but is higher than the second threshold value of 25, the storage system controller may allocate storage device 1902d for the storage of parity shard 1908.

Storage device 1902e has a corresponding result of 10. Because storage device 1902e has a corresponding result that is below the second threshold value of 25, the storage system controller may allocate storage device 1902e for the storage of global parity shard 1910.

It should be noted that the numerical values of the results and thresholds, the number of thresholds, the number of storage devices, data shards, parity shards, and/or global parity shards are shown for illustrative purposes only. Embodiments of the disclosure may utilize any number of storage devices, thresholds, shards, etc. to determine which storage devices to allocate for the storage of different shards of data.

In some embodiments, a RAID stripe may have shards of data and/or parity on multiple storage devices in a single failure domain. For example, a RAID stripe may have data and/or parity stored on two storage devices of a single blade of a storage system. In such an embodiment, the storage system controller may rank the load on a storage device as follows: (1) multiple data shards from a single RAID sub-stripe and no parity shards, (2) a single data shard from each RAID sub-stripe and local parity for a sub-stripe, (3) a single data shard from each sub-stripe and global parity for the full RAID stripe, or (4) a single data shard from each sub-stripe and no parity shards, where the highest performance storage devices are selected for rank 1 and the performance decreases where the lowest performance storage devices are selected for rank 4.

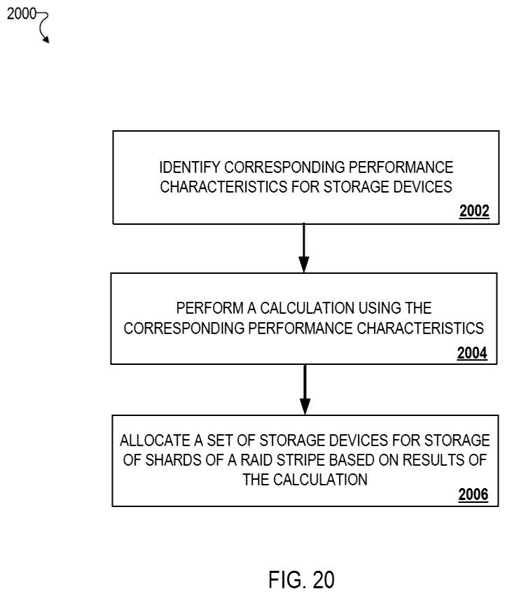

FIG. 20 is an example method 2000 to allocate storage devices based on performance characteristics, in accordance with embodiments of the disclosure. In general, the method 2000 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a storage system controller may perform the method 2000.

Method 2000 may begin at block 2002, where the processing logic identifies corresponding performance characteristics for storage devices of a storage system.

At block 2004, the processing logic performs a calculation using the corresponding characteristics of the storage devices.

At block 2006, the processing logic allocates a set of storage devices for storage of shards of a RAID stripe based on results of the calculation.

Advantages and features of the present disclosure can be further described by the following statements:

1. A method of identifying corresponding performance characteristics for a plurality of storage devices; performing a calculation using the corresponding performance characteristics for the plurality of storage devices; and allocating, by a processing device of a storage controller operatively coupled to the plurality of storage devices, a set of storage devices of the plurality of storage devices for storage of shards of a redundant array of independent drives (RAID) stripe based on results of the calculation.

2. The method of statement 1, wherein allocating the set of storage devices for storage of the shards of the RAID stripe based on the results of the calculation further comprises allocating a first subset of the set of storage devices for storing the shards of the RAID stripe comprising user data, the first subset of the set of storage devices having corresponding results of the calculation that exceed a first threshold.

3. The method of any of statements 1-2, wherein allocating the set of storage devices for storage of the shards of the RAID stripe based on the results of the calculation further comprises allocating a second subset of the set of storage devices for storing shards of the RAID stripe comprising parity for the RAID stripe, the second subset of the set of storage devices having corresponding results of the calculation that are below the first threshold and exceed a second threshold.

4. The method of any of statements 1-3, wherein allocating the set of storage devices for storage of the shards of the RAID stripe based on the results of the calculation further comprises allocating a third subset of the set of storage devices for storing shards of the RAID stripe comprising global parity, the third subset of the set of storage devices having corresponding results of the calculation that are below the second threshold.

5. The method of any of statements 1-4, wherein the plurality of storage devices comprises solid-state storage devices having erase blocks that are directly mapped.

6. The method of any of statements 1-5, wherein the performance characteristics comprise one or more of latency, bandwidth, or available storage capacity.

7. The method of any of statements 1-6, wherein corresponding weights are applied to the performance characteristics when performing the calculation.

8. A storage system comprising a plurality of storage devices; and a storage controller, operatively coupled to the plurality of storage devices, the storage controller comprising a processing device configured to perform any of statements 1-7.

9. A non-transitory computer readable storage medium storing instructions which, when executed, cause a processing device to perform any of statements 1-7.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

With the above embodiments in mind, it should be understood that the embodiments might employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing. Any of the operations described herein that form part of the embodiments are useful machine operations. The embodiments also relate to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

A module, an application, a layer, an agent or other method-operable entity could be implemented as hardware, firmware, or a processor executing software, or combinations thereof. It should be appreciated that, where a software-based embodiment is disclosed herein, the software can be embodied in a physical machine such as a controller. For example, a controller could include a first module and a second module. A controller could be configured to perform various actions, e.g., of a method, an application, a layer or an agent.

The embodiments can also be embodied as computer readable code on a tangible non-transitory computer readable medium. The computer readable medium is any data storage device that can store data, which can be thereafter read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer system so that the computer readable code is stored and executed in a distributed fashion. Embodiments described herein may be practiced with various computer system configurations including hand-held devices, tablets, microprocessor systems, microprocessor-based or programmable consumer electronics, minicomputers, mainframe computers and the like. The embodiments can also be practiced in distributed computing environments where tasks are performed by remote processing devices that are linked through a wire-based or wireless network.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

In various embodiments, one or more portions of the methods and mechanisms described herein may form part of a cloud-computing environment. In such embodiments, resources may be provided over the Internet as services according to one or more various models. Such models may include Infrastructure as a Service (IaaS), Platform as a Service (PaaS), and Software as a Service (SaaS). In IaaS, computer infrastructure is delivered as a service. In such a case, the computing equipment is generally owned and operated by the service provider. In the PaaS model, software tools and underlying equipment used by developers to develop software solutions may be provided as a service and hosted by the service provider. SaaS typically includes a service provider licensing software as a service on demand. The service provider may host the software, or may deploy the software to a customer for a given period of time. Numerous combinations of the above models are possible and are contemplated.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A storage system, comprising:
a plurality of storage devices; and
a storage controller, operatively coupled to the plurality of storage devices, the storage controller comprising a processing device configured to:
identify corresponding performance characteristics for the plurality of storage devices;
perform a calculation using the corresponding performance characteristics for the plurality of storage devices; and
allocate a set of storage devices of the plurality of storage devices for storage of shards of a redundant array of independent drives (RAID) stripe based on results of the calculation.

2. The storage system of claim 1, wherein to allocate the set of storage devices for storage of the shards of the RAID stripe based on the results of the calculation, the processing device is further configured to:
allocate a first subset of the set of storage devices for storing the shards of the RAID stripe comprising user data, the first subset of the set of storage devices having corresponding results of the calculation that exceed a first threshold.

3. The storage system of claim 2, wherein to allocate the set of storage devices for storage of the shards of the RAID stripe based on the results of the calculation, the processing device is further configured to:
allocate a second subset of the set of storage devices for storing shards of the RAID stripe comprising parity for the RAID stripe, the second subset of the set of storage devices having corresponding results of the calculation that are below the first threshold and exceed a second threshold.

4. The storage system of claim 3, wherein to allocate the set of storage devices for storage of the shards of the RAID stripe based on the results of the calculation, the processing device is further configured to:
allocate a third subset of the set of storage devices for storing shards of the RAID stripe comprising global parity, the third subset of the set of storage devices having corresponding results of the calculation that are below the second threshold.

5. The storage system of claim 1, wherein the plurality of storage devices comprises solid-state storage devices having erase blocks that are directly mapped.

6. The storage system of claim 1, wherein the performance characteristics comprise one or more of latency, bandwidth, or available storage capacity.

7. The storage system of claim 1, wherein corresponding weights are applied to the performance characteristics when performing the calculation.

8. A method, comprising:
identifying corresponding performance characteristics for a plurality of storage devices;
performing a calculation using the corresponding performance characteristics for the plurality of storage devices; and
allocating, by a processing device of a storage controller operatively coupled to the plurality of storage devices, a set of storage devices of the plurality of storage devices for storage of shards of a redundant array of independent drives (RAID) stripe based on results of the calculation.

9. The method of claim 8, wherein allocating the set of storage devices for storage of the shards of the RAID stripe based on the results of the calculation further comprises:
allocating a first subset of the set of storage devices for storing the shards of the RAID stripe comprising user data, the first subset of the set of storage devices having corresponding results of the calculation that exceed a first threshold.

10. The method of claim 9, wherein allocating the set of storage devices for storage of the shards of the RAID stripe based on the results of the calculation further comprises:
allocating a second subset of the set of storage devices for storing shards of the RAID stripe comprising parity for the RAID stripe, the second subset of the set of storage devices having corresponding results of the calculation that are below the first threshold and exceed a second threshold.

11. The method of claim 10, wherein allocating the set of storage devices for storage of the shards of the RAID stripe based on the results of the calculation further comprises:
allocating a third subset of the set of storage devices for storing shards of the RAID stripe comprising global parity, the third subset of the set of storage devices having corresponding results of the calculation that are below the second threshold.

12. The method of claim 8, wherein the plurality of storage devices comprises solid-state storage devices having erase blocks that are directly mapped.

13. The method of claim 8, wherein the performance characteristics comprise one or more of latency, bandwidth, or available storage capacity.

14. The method of claim 8, wherein corresponding weights are applied to the performance characteristics when performing the calculation.

15. A non-transitory computer readable storage medium storing instructions which, when executed, cause a processing device of a storage controller to:
identify corresponding performance characteristics for a plurality of storage devices;
perform a calculation using the corresponding performance characteristics for the plurality of storage devices; and
allocate a set of storage devices of the plurality of storage devices for storage of shards of a redundant array of independent drives (RAID) stripe based on results of the calculation.

16. The non-transitory computer readable storage medium of claim 15, wherein to allocate the set of storage devices for storage of the shards of the RAID stripe based on the results of the calculation, the processing device is further configured to:
allocate a first subset of the set of storage devices for storing the shards of the RAID stripe comprising user data, the first subset of the set of storage devices having corresponding results of the calculation that exceed a first threshold.

17. The non-transitory computer readable storage medium of claim 16, wherein to allocate the set of storage devices for storage of the shards of the RAID stripe based on the results of the calculation, the processing device is further configured to:
allocate a second subset of the set of storage devices for storing shards of the RAID stripe comprising parity for the RAID stripe, the second subset of the set of storage devices having corresponding results of the calculation that are below the first threshold and exceed a second threshold.

18. The non-transitory computer readable storage medium of claim 17, wherein to allocate the set of storage devices for storage of the shards of the RAID stripe based on the results of the calculation, the processing device is further configured to:
allocate a third subset of the set of storage devices for storing shards of the RAID stripe comprising global parity, the third subset of the set of storage devices having corresponding results of the calculation that are below the second threshold.

19. The non-transitory computer readable storage medium of claim 15, wherein the plurality of storage devices comprises solid-state storage devices having erase blocks that are directly mapped.

20. The non-transitory computer readable storage medium of claim 15, wherein corresponding weights are applied to the performance characteristics when performing the calculation.
